(19) United States
(12) Patent Application Publication
(10) Pub. No.: US 2020/0235250 A1
(43) Pub. Date: Jul. 23, 2020

(54) POWER COLLECTOR

(71) Applicant: FRESCHFIELD PLC, London (GB)

(72) Inventor: Randolph Allen ST JAMES, London (GB)

(73) Assignee: FRESCHFIELD PLC, London (GB)

(21) Appl. No.: 16/632,220

(22) PCT Filed: Jul. 17, 2018
(86) PCT No.: PCT/GB2018/052022

§ 371 Date: Jan. 17, 2020

(30) Foreign Application Priority Data
Jul. 18, 2017 (GB) 1711546.0

(51) Int. Cl. H01L 31/0216; H01L 31/02; H01L 31/053; H01L 31/054; H02S 20/22; H01L 31/05; H02J 3/38

(52) U.S. Cl. CPC H01L 31/02168; H01L 31/02021; H01L 31/053; H02J 2300/24; H02S 20/22; H01L 31/0512; H02J 3/381; H01L 31/0547

(57) ABSTRACT

Embodiments provide a photovoltaic cell, including: a first conduction layer; a second conduction layer; a photonic absorption layer electrically coupled to the first conduction layer, the photonic absorption layer is tuned to absorb incident light at a first wavelength of the incident light to generate a first electric current along the first conduction layer; and a plasma-sonic layer electrically coupled to the photonic absorption layer and the second conduction layer, the plasma-sonic layer includes nanoparticles, the nanoparticles are tuned to a second wavelength of the incident light that induces electrons to oscillate at a surface of the nanoparticles.

### BACKGROUND

### Field

The present disclosure generally relates to power collectors and, more specifically, to power collectors capable of convening visible light energy and/or infrared energy into electricity.

### Description of Related Art

Typical photovoltaic cells are implemented using bulk semiconductor materials, such as silicon, to generate electric power. The generation of electricity of such bulk semiconductor materials relies on absorbing photons with energy greater than the bandgaps of the bulk semiconductor material, which is corresponds to energies greater than the electromagnetic energy in the infrared spectrum. Consequently, photovoltaic cells made from conventional bulk semiconductor materials neither absorb nor generate electricity from infrared energy. Notably, half of the solar energy reaching the Earth has wavelengths in the infrared spectrum, which means that conventional photovoltaic cells neglect half of the solar energy reaching the Earth. The challenge is to develop a photovoltaic cell to capture electromagnetic energy within the infrared spectrum.

### BRIEF SUMMARY

The following presents a simplified summary of one or more examples in order to provide a basic understanding of such examples. This summary is not an extensive overview of all contemplated examples and is intended to neither identify key or critical elements of all examples nor delineate the scope of any or all examples. Its purpose is to present some concepts of one or more examples in a simplified form as a prelude to the more detailed description that is presented below.

According to a first aspect, there is provided a photovoltaic cell, comprising: a first conduction layer, a second conduction layer, a photonic absorption layer electrically coupled to the first conduction layer, the photonic absorption layer is tuned to absorb incident light at a first wavelength of the incident light to generate a first electric current along the first conduction layer; and a plasma-sonic (also known as plasmonic) layer electrically coupled to the photonic absorption layer and the second conduction layer, the plasma-sonic layer includes nanoparticles, the nanoparticles are tuned to a second wavelength of the incident light that induces electrons to oscillate at a surface of the nanoparticles.

According to a second aspect, there is provided a solar photovoltaic collector, comprising: a photovoltaic cell of the first aspect; a first electrode electrically coupled to the first conduction layer, and a second electrode electrically coupled to the plasma-sonic layer and the photonic absorption layer, wherein the first electrode is electrically isolated from the second electrode.

According to a third aspect, there is provided a solar photovoltaic array, comprising: a plurality of solar photovoltaic collectors of the second aspect, configured to tessellate with each other.

In accordance with some examples, a photovoltaic cell comprises a first conduction layer; a second conduction layer; a photonic absorption layer electrically coupled to the first conduction layer (the photonic absorption layer configured to absorb incident light shorter than a first wavelength of the incident light to generate a first electric current along the first conduction layer); and a plasma-sonic layer electrically coupled to the photonic absorption layer and the second conduction layer, and the plasma-sonic layer includes nanoparticles configured to induce electrons to oscillate at a surface of the nanoparticles shorter than a second wavelength of the incident light.

In some examples, the photovoltaic cell further includes a rectifier bridge configured to provide a same polarity of output with respect to reference ground for any polarity at a first input or second input, wherein the first input is electrically coupled to the second conduction layer, and the second input is electrically coupled to the plasma-sonic layer. In some examples, the photovoltaic cell further includes an energy cell electrically coupled across the output of the rectifier bridge and the reference ground. In some examples, the photovoltaic cell further includes a substrate configured to hermetically seal the photonic absorption layer, the plasma-sonic layer, and the second conduction layer.

In accordance with some examples, a solar photovoltaic collector comprises at least one photovoltaic cell having a first conduction layer and a plasma-sonic layer, a first electrode electrically connected to the first conduction layer, and a second electrode electrically connected to the plasma-sonic layer and the photonic absorption layer. The first electrode is electrically isolated from the second electrode. The at least one photovoltaic cell further includes a second conduction layer, and a photonic absorption layer electrically coupled to the first conduction layer. The photonic absorption layer is configured to absorb incident light shorter than a first wavelength of the incident light to generate a first electric current along the first conduction layer, and where the plasma-sonic layer is electrically coupled to the photonic absorption layer and the second conduction layer, the plasma-sonic layer includes nanoparticles configured to induce electrons to oscillate at a surface of the nanoparticles shorter than a second wavelength of the incident light.

In some examples, the solar photovoltaic collector further includes a rectifier bridge configured to provide a same polarity of output with respect to reference ground for any polarity at a first input or second input, wherein the first input is electrically coupled to the second conduction layer, and the second input is electrically coupled to the plasma-sonic layer. In some examples, the solar photovoltaic collector further includes an energy cell electrically coupled across the output of the rectifier bridge and the reference ground. In some examples, the solar photovoltaic collector further includes a substrate configured to hermetically seal the photonic absorption layer, the plasma-sonic layer, and the second conduction layer.

In some examples, the solar photovoltaic collector further includes a power transfer circuit affixed to the photovoltaic collector and electrically coupled to the first electrode and the second electrode, wherein the power transfer circuit is configured to sense instantaneous power of an electrical power grid, sense instantaneous power generated from the photovoltaic collector, and sweep power generated from the photovoltaic collector to the electrical power grid.

In accordance with some examples, a solar photovoltaic collector array, comprises a plurality of solar photovoltaic collectors configured to tessellate with each other, and each photovoltaic collector includes: at least one photovoltaic cell having a first conduction layer and a plasma-sonic layer, a first electrode electrically connected to the first conduction layer, and a second electrode electrically connected to the plasma-sonic layer and the photonic absorption layer. The first electrode is electrically isolated from the second electrode. The at least one photovoltaic cell further includes a second conduction layer and a photonic absorption layer electrically coupled to the first conduction layer and the second conduction layer. The photonic absorption layer is configured to absorb incident light shorter than a first wavelength of the incident light to generate a first electric current along the first conduction layer, and where the plasma-sonic layer is electrically coupled to the photonic absorption layer and the second conduction layer, the plasma-sonic layer includes nanoparticles configured to induce electrons to oscillate at a surface of the nanoparticles shorter than a second wavelength of the incident light.

In some examples, the solar photovoltaic collector array further includes a rectifier bridge configured to provide the same polarity of output with respect to reference ground for any polarity at a first input or second input, wherein the first input is electrically coupled to the second conduction layer and the second input is electrically coupled to the plasma-sonic layer. In some examples, the solar photovoltaic collector array further includes an energy cell electrically coupled across the output of the rectifier bridge and the reference ground. In some examples, each photovoltaic collector further includes a substrate configured to hermetically seal the photonic absorption layer, the plasma-sonic layer, and the second conduction layer.

In some examples, each respective solar photovoltaic collector further includes a power transfer circuit affixed to the solar photovoltaic collector and electrically coupled to the first electrode and the second electrode, wherein the power transfer circuit is configured to sense instantaneous power of an electrical power grid, sense instantaneous power generated from the photovoltaic collector, and sweep power generated from the photovoltaic collector to the electrical power grid. In some examples, solar photovoltaic collector array further includes a mounting assembly configured to bracket the plurality of solar photovoltaic collectors of a building. Photovoltaic cells, photovoltaic collectors and photovoltaic arrays can be used in a number of applications, such as, for example, buildings, pavements, walls, homes, vehicles, planes, trains and ships.

### BRIEF DESCRIPTION OF THE FIGURES

For a better understanding of the various described examples, reference should be made to the description below and in conjunction with the following figures, in which like reference numerals refer to corresponding parts throughout the figures.

FIGS. 1A and 1B illustrate a front and side view of an exemplary plasma-sonic-based photovoltaic collector.

FIG. 2 illustrates front views of various shapes of exemplary plasma-sonic-based photovoltaic cells used for a tessellating a photovoltaic collector array.

FIG. 3 illustrates various side views of exemplary plasma-sonic-based photovoltaic collectors.

FIGS. 4A-4C illustrate various cross-sectional views of exemplary plasma-sonic-based photovoltaic collectors.

FIGS. 5A and 5B illustrate various cross-sectional views of exemplary hybrid plasma-sonic-based photovoltaic collectors.

FIGS. 6A-6R illustrate cross-sectional views of various plasma-sonic-based and/or photonic based photovoltaic collectors.

FIG. 7 illustrates an exploded view of exemplary plasma-sonic-based photovoltaic collector.

FIG. 8 illustrates an ISO view and bracketing coupler for an exemplary hybrid plasma-sonic-based photovoltaic collector.

FIGS. 9A and 9B illustrate an array of tessellated plasma-sonic-based collectors.

FIG. 10 illustrates a tessellated array that envelop one or more buildings.

FIG. 11 illustrates a conceptual data flow diagram illustrating the data flow between different hardware of a hybrid plasma-sonic-based photovoltaic collector that implements a plasma-sonic generator and a photonic generator.

### DETAILED DESCRIPTION

The detailed description set forth below in connection with the appended drawings is intended as a description of various configurations and is not intended to represent the only configurations in which the concepts described herein can be practiced. The detailed description includes specific details for the purpose of providing a thorough understanding of various concepts. However, it will be apparent to those skilled in the art that these concepts can be practiced without these specific details. In some instances, well-known structures and components are shown in block diagram form in order to avoid obscuring such concepts.

Examples of photovoltaic collectors will now be presented with reference to various electronic devices. These electronic devices will be described in the following detailed description and illustrated in the accompanying drawing by various blocks, components, circuits, steps, etc. (collectively referred to as “elements”).

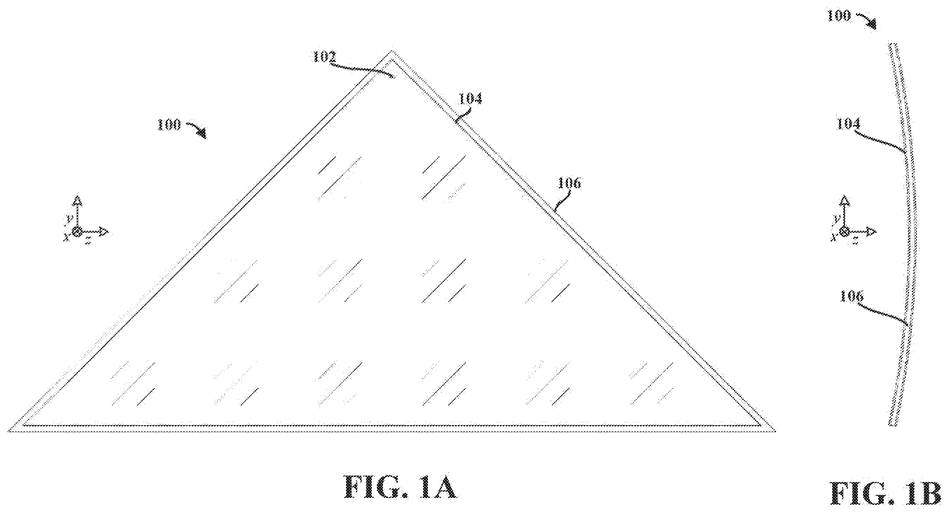

By way of example, an element, or any portion of an element, or any combination of elements of the microcontroller/processor 102 (FIG. 1A) can be implemented using one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionalities described throughout this disclosure. One or more processors in the processing system can execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more examples, the aspects of photovoltaic collectors can be implemented in hardware, software, or any combination thereof. The aspects implemented in software can be stored or encoded as one or more instructions or code on a computer-readable medium. Computer-readable media can include transitory or non-transitory computer storage media for carrying or having computer-executable instructions or data structures stored thereon. Both transitory and non-transitory storage media can be any available media that can be accessed by a computer as part of the processing system. By way of example, and not limitation, such computer-readable media can include a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer-executable code in the form of instructions or data structures accessible by a computer. Further, when information is transferred or provided over a network or another communications connection (either hardwired, wireless, or combination thereof) to a computer, the computer or processing system properly determines the connection as a transitory or non-transitory computer-readable medium, depending on the particular medium. Thus, any such connection is properly termed a computer-readable medium. Combinations of the above should also be included within the scope of the computer-readable media. Non-transitory computer-readable media exclude signals per se and the air interface.

The present disclosure describes a hybrid photovoltaic collector that includes a photonic absorption layer and a plasma-sonic layer, alternatively referred to as a plasmonic layer. The photonic absorption layer is configured to generate electron-hole pairs from incident light. In some configurations, the photonic absorption layer is configured to generate electron-hole pairs from incident light with wavelengths shorter than 700 nanometers, which corresponds to frequencies in the visible and ultraviolet spectrum in some configurations, the photonic absorption layer is configured to generate electron-hole pairs from incident light with wavelengths greater than 700 nanometers, which corresponds to frequencies in the infrared spectrum. The generation of the electron-hole pairs of the photonic absorption layer induces a direct electric current in a conduction layer that is electrically coupled to a power collar at a periphery of the hybrid photovoltaic collector. In addition to the photonic absorption layer, the plasma-sonic layer functions in parallel to provide electrical current to the power collar. In particular, the plasma-sonic layer, with plasmonic-type properties, is configured to induce charged carrier (e.g., electrons, holes, etc.) oscillations from incident light. In some configurations, the plasma-sonic layer is configured to induce charged carrier (e.g., electrons, holes, etc.) oscillations from incident light shorter than 700 nanometers, which corresponds to frequencies in the visible and ultraviolet spectrum. In some configurations, the plasma-sonic layer is configured to induce charged carrier (e.g., electrons, holes, etc.) oscillations from incident light longer than 700 nanometers, which corresponds to frequencies in the infrared spectrum. The charged carriers (e.g., electrons, holes, etc.) generate an alternating current that, when coupled to the power collar at the periphery of the hybrid photovoltaic collector rectifies and directs the current to an energy cell or inverter for future use.

FIGS. 1A and 1B illustrate a front and side view of an exemplary plasma-sonic-based photovoltaic collector 100. In this example, the photovoltaic collector 100 has a triangular shape and includes a microcontroller/processor 102, a power collar 104, and an energy cell 106. The photovoltaic collector 100 can be an equilateral triangular shape, where each of the three edges has the same length, an isosceles triangular shape, where two of the three edges have the same length, or a scalene triangular shape, where none of the three edges have the same length.

As depicted in FIG. 1A, the microcontroller/processor 102 is situated near an apex of a triangle corner. In this instance, the microcontroller/processor 102 is embedded within the photovoltaic collector 100. That is, the microcontroller/processor 102 is fabricated within one or more protective layers of the photovoltaic collector 100 so as to be hermetically sealed within the photovoltaic collector 100, which protects the microcontroller/processor 102 from the elements (e.g., rain, snow, wind, dust, etc.) and ensures that peripheries to the microcontroller/processor 102 are correctly connected at fabrication. In some configurations, the microcontroller/processor 102 is provided on an insulating surface and electrically coupled to the portions of the photovoltaic collector 100. As such, the microcontroller/processor 102 is standalone from the photovoltaic collector 100, and either can be modified individually. In some configurations, the microcontroller/processor 102 includes redundancy. For example, in some instances, a first microcontroller/processor 102 can be embedded and a second microcontroller/processor 102 can be provided on an insulating surface and electrically coupled to the portions of the photovoltaic collector 100. In other configurations, microcontroller/processors 102 are situated at two or more apexes of a triangle corner.

Further, the microcontroller/processor 102 includes memory electrically coupled to one or more processors. In general, the microcontroller/processor 102 includes one or more programmable input/output peripherals 1104. For example, at least one programmable input/output peripheral can be a voltage sensor situated at an anode and/or cathode of the energy cell 106. In such a configuration, the voltage sensor is configured to detect the instantaneous voltage at an anode and/or a cathode of the photovoltaic collector 100 or of the energy cell 106. In some examples, at least one programmable input/output peripheral is a current sensor configured to detect current from the anode and/or the cathode of the photovoltaic collector 100 or of the energy cell 106. In some examples, at least one programmable input/output peripheral is an impedance sensor configured to detect the impedance of an electrical power grid. In some examples, at least one programmable input/output peripheral is a communication interface circuit to communicate with a power bridge or power inverter. In some instances, the communication interface circuit includes a universal serial bus (USB) configured to interface with an energy cell, power bridge, power inverter, grid-tie, or other electronic device to balance the load and facilitate power distribution.

As depicted in FIG. 1A, the power collar 104 is situated around a periphery of the edges of the triangular photovoltaic collector 100. The power collar 104 is configured to direct charged carriers (e.g., electrons, holes, etc.) to an energy cell or inverter. The power collar 104 is electrically coupled to at least one conduction layer and is made from semiconductor materials, such as silicon (polycrystalline silicon or monocrystalline silicon), germanium, cadmium telluride, copper indium gallium selenide, gallium arsenide (GaAs), indium gallium arsenide, and the like. The power collar 104 is further configured to electrically couple with one or more adjacent photovoltaic collectors. In some configurations, the power collar 104 includes a socketing feature, such as a male or a female connector to connect (e.g., electrically couple) with adjacent photovoltaic collectors. In some examples, a first photovoltaic collector 100 interlocks with a second photovoltaic collector 100 along a respective edge of the photovoltaic collector 100 so as to electrically couple the power collars 104 of each respective photovoltaic collector 100. In some instances, one or more adjacent photovoltaic collectors tessellate (e.g., situated with little to no gap between adjacent photovoltaic collectors) with the photovoltaic collector 100.

As depicted in FIG. 1A, the energy cell 106 is situated at edges of the photovoltaic collector 100. The energy cell 106 includes an anode (e.g., positive terminal) and a cathode (e.g., negative terminal). The energy cell 106 can be a battery, a capacitor, or other electrical energy storing device capable of storing a charge. The energy cell 106 provides a reservoir of electrical storage and provides a low-impedance path to the alternating current (e.g., I_{AC}) thereby cancelling cyclical charges (e.g. ripple). In some examples, the energy cell 106 is a lithium-ion (li-ion) cell. In some instances, the energy cell 106 is a battery with one or more energy cells. In some instances, the energy cell 106 is a li-ion battery. In some instances, the energy cell 106 is a lithium polymer battery. In some examples, the energy cell 106 is based on at least one of lithium cobalt oxide (LiCoO₂), lithium iron phosphate (LiFePO₄, lithium ion manganese oxide (LiMn₂O₄, Li₂MnO₃, or LMO), lithium nickel manganese cobalt oxide (LiNiMnCoO₂ or NMC), lithium nickel cobalt aluminum oxide (LiNiCoAlO₂ or NCA), lithium titanate (Li₄Ti₅O₁₂ or LTO), and lithium-sulfur (LS). In some examples, the energy cell 106 is a nickel-metal hydride (NiMH) battery.

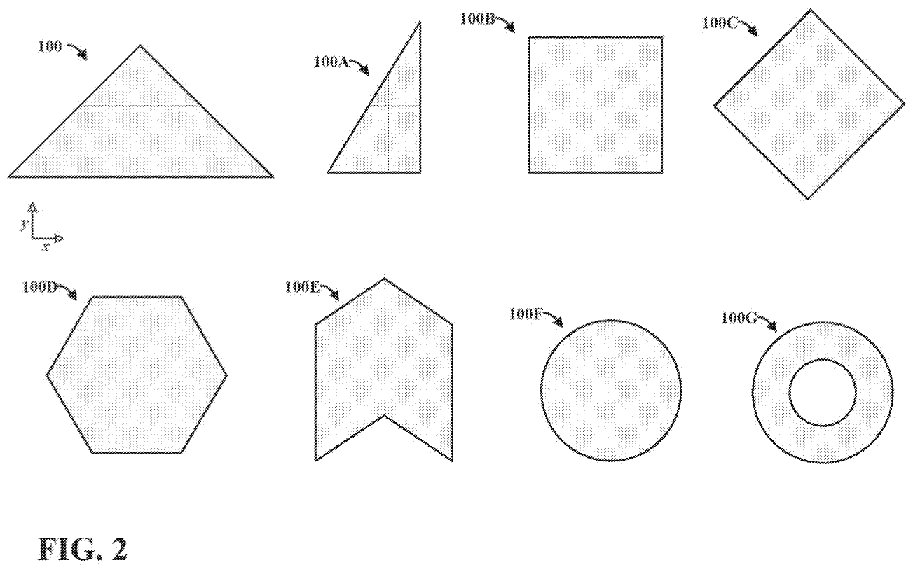

The position of the energy cell 106 and the power collar 104 are at the periphery and edges of the photovoltaic collector 100 so as to tessellate with adjacent photovoltaic collectors without overlaps or gaps. FIG. 2 illustrates front views of various shapes of exemplary plasma-sonic-based photovoltaic cells (e.g., photovoltaic collectors 100A-100G) used for tessellating a photovoltaic collector array. For example, the photovoltaic collector 100 when viewed from the font can be a polygon. For instance, the photovoltaic collector can be an equilateral/isosceles triangular photovoltaic collector 100 or a scalene triangular photovoltaic collector 100A. In some instances, the photovoltaic collector 100 is a square/rectangular photovoltaic collector 100B. In some instances, the photovoltaic collector 100 is a rhombic/diamond-shaped photovoltaic collector 100C. In some instances, the photovoltaic collector 100 is a hexagonal photovoltaic collector 100D. In some instances, the photovoltaic collector 100 is an arrow-shaped photovoltaic collector 100E. In other examples, the photovoltaic collector 100 when viewed from the font is curved. For instance, the photovoltaic collector 100 can have a circular photovoltaic collector 100F or a ring-shaped photovoltaic collector 100G. It should be appreciated that one or more different shaped photovoltaic collectors 100 can be tessellated together. For example, the circular photovoltaic collector 100F can be interlocked (e.g., tessellated, electrically coupled) into the opening of ring-shaped 1000. Likewise, hexagonal photovoltaic collector 100D can be interlocked (e.g., tessellated, electrically coupled) with any of the triangular photovoltaic collectors 100, the scalene triangular photovoltaic collector 100A, the square/rectangular photovoltaic collector 100B, the rhombic/diamond-shaped photovoltaic collector 100C, and the arrow-shaped photovoltaic collector 100E.

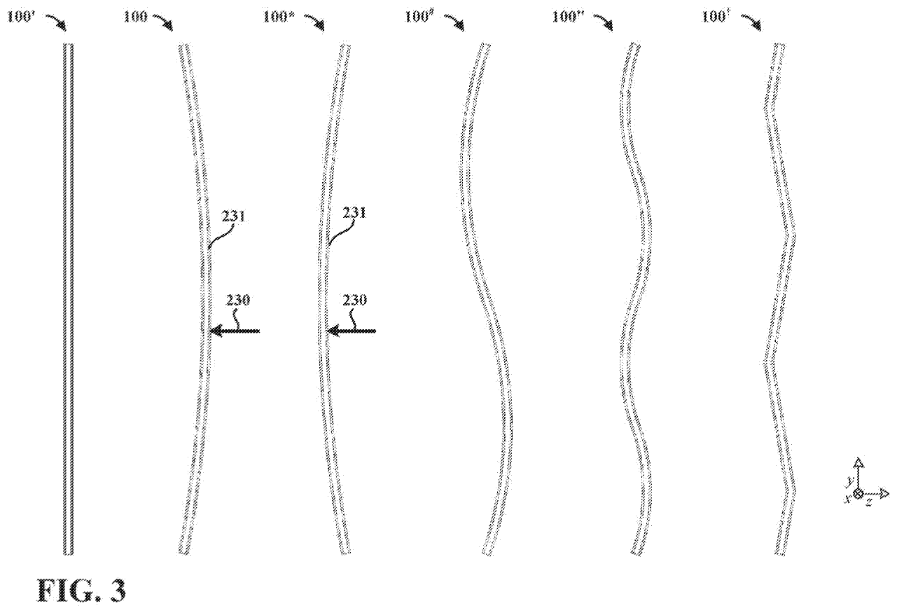

As depicted in FIG. 18B, the photovoltaic collector 100 can also be non-planar (e.g., curved). A curved photovoltaic collector can lens incident light thereby increasing absorption efficiency on a photonic absorption layer or increasing efficiency from charged carrier (e.g., electrons, holes, etc.) oscillations extraction in a plasma-sonic layer. Other curved and/or jagged shapes are contemplated. For example, FIG. 3 illustrates various side views of exemplary plasma-sonic-based photovoltaic collectors (e.g., cells, panels). In particular, a photovoltaic collector can be flat or planar as depicted in flat photovoltaic collector 100′ (FIG. 3). In some examples, the photovoltaic collector when viewed from the side can be elongated toward an incident surface 231 surface of incident light as depicted in the triangular photovoltaic collector 100 (e.g., convex) or can be elongated away from an incident surface 231, as depicted in the concave photovoltaic collector 100* (FIG. 3).

In some examples, the photovoltaic collector when viewed from the side can include a single undulation as depicted in single-undulated photovoltaic collector 100* (FIG. 3). In some examples, the photovoltaic collector when viewed from the side can include multiple undulations as depicted in the multiple-undulated photovoltaic collector 100″ (FIG. 3). In some examples, the photovoltaic collector when viewed from the side can be jagged, as depicted in jagged photovoltaic collector 100^{†}. In some configurations, the solar photovoltaic collector 100 is non-planar along a light incident surface. In some configurations, the solar photovoltaic collector 100 is curved along a light incident surface at an are angle between 0 to 23.5 degrees.

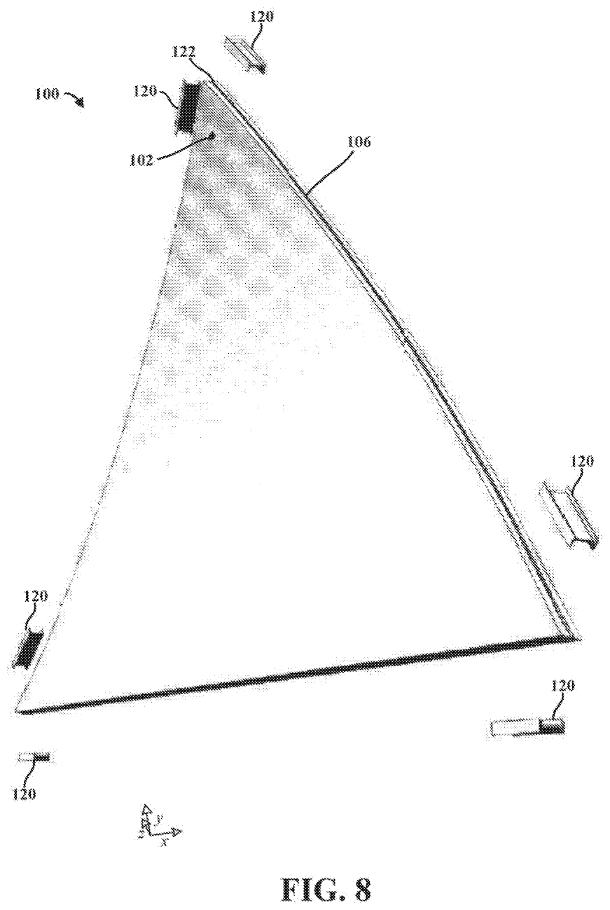

The curvature or surface of various side views of the photovoltaic collectors 100 can change with direction. For example, a surface can elongate towards incident light as depicted in the triangular photovoltaic collector 100 (e.g., convex) of FIG. 3 and can extend in the x-y plane and the y-z plane to form paraboloid-like or spherical-like surface, etc. (FIG. 8). It should also be appreciated that various combinations of the above shapes are contemplated. For example, a photovoltaic collector can have multiple undulations (e.g., 100″ (FIG. 3)) and be hexagonally shaped (e.g., 100D (FIG. 2)).

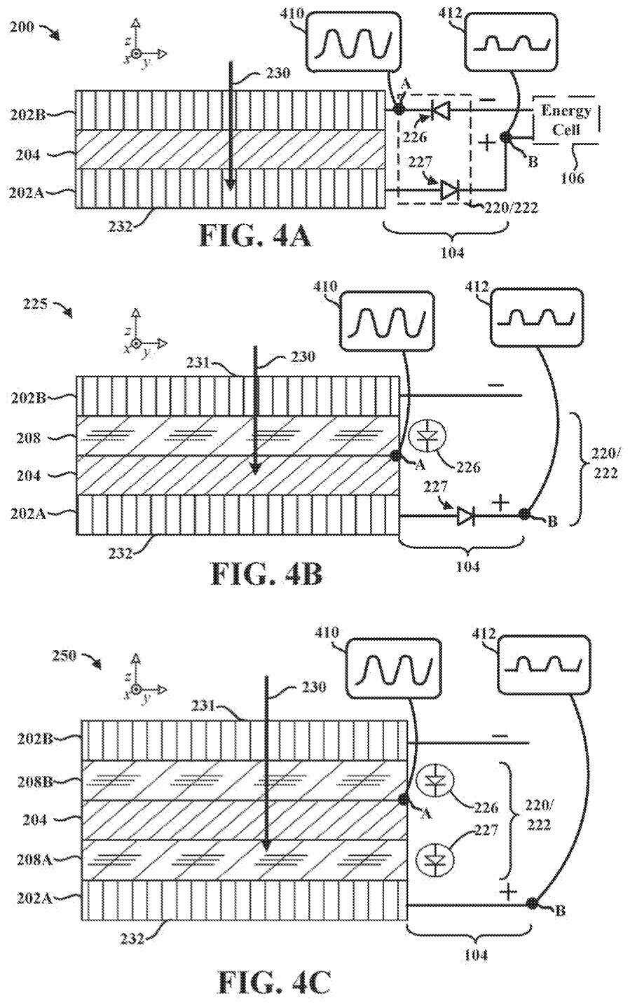

FIGS. 4A-4C illustrate various cross-sectional views of exemplary plasma-sonic-based photovoltaic cells. The plasma-sonic photovoltaic cell cross section 200 depicted in FIG. 4A includes a first conduction layer 202A, a plasma-sonic layer 204, and a second conduction layer 202B. The first conduction layer 202A and the second conduction layer 202B can be made of a conductive material, such as metal, alloy, or a semiconductor (e.g., copper, aluminum, polysilicon, stainless steel, and the like). The first conduction layer 202A and the second conduction layer 202B can also be made from a semimetal, such as graphene, arsenic, antimony, etc. In some examples, the first conduction layer 202A and/or the second conduction layer 202B is made from a p-doped or n-doped semimetal (e.g., graphene, arsenic, antimony, etc). In some examples, any one of the first conduction layer 202A and the second conduction layer 202B is made from conductive nanowires (e.g., metallic nanowires, semimetal nanowires, doped semimetal nanowires) or nanotubes (e.g., carbon nanotubes). As depicted in FIG. 4A, a surface of both the first conduction layer 202A and the second conduction layer 202B is electrically coupled to the plasma-sonic layer 204 along an interface in a transverse direction (e.g., x-y plane).

The plasma-sonic layer 204 can be made from a dielectric (e.g., electrical insulator) or semiconductor. The plasma-sonic layer 204 can be a polymer or a ceramic. In some examples, the plasma-sonic layer 204 is a polycarbonate. In general, the plasma-sonic layer 204 is non-conductive to direct current (e.g., I_{DC}) but is conductive to alternating current (e.g., I_{AC}). As such, plasma-sonic layer 204 is configured to be polarized in the presence of an electric field. This polarization causes positive charges to be displaced toward the electric field and negative charges to be displaced away from the electric field, which creates an internal electric field thereby reducing the overall electric field within the dielectric itself. The plasma-sonic layer 204 includes nanoparticles that couple with the polarization of the dielectric and induce electrons to oscillate at a surface of the nanoparticles within the dielectric for certain wavelengths of incident light. It should be appreciated that the induced electron oscillations occur throughout the dielectric and are not simply concentrated at an interface between the dielectric and an adjacent conduction layer (e.g., the first conduction layer 202A and the second conduction layer 202B). In some instances, the wavelength of incident light is at a resonance wavelength of the charged carriers (e.g., electrons, holes, etc.).

The wavelengths of incident light that induce electrons to oscillate at a surface of the nanoparticles correlate with the size of the nanoparticles. As such, the wavelengths of incident light can be tuned by increasing or decreasing the size of the nanoparticles. In some examples, the wavelength of incident light is tuned to be longer than 700 nanometers, which corresponds to frequencies in the infrared spectrum. In some examples, the wavelength of incident light is tuned shorter than 700 nanometers, which corresponds to frequencies in the visible light and ultra-violet spectrum.

In some examples, the plasma-sonic layer 204 is an electrical insulator. In some examples, the plasma-sonic layer 204 is a dielectric with a complex dielectric constant. In some examples, the nanoparticles contribute to the plasma-sonic layer 204 having a complex dielectric constant. The nanoparticles can be homogenously dispersed (e.g., mixed) throughout the plasma-sonic layer 204 and can be a dielectric, a semiconductor, a semimetal, or a metal. The shape of the nanoparticles can be substantially similar or vary. The shape can have any one of a conical, rectangular, bi-pyramidal, tetrahedral, cubical, octahedral, cylindrical, ellipsoidal, or spherical shape. In some examples, the nanoparticles are dielectrics that are suspended in a polymer matrix. In some examples, the nanoparticles are dielectrics that are suspended in a polycarbonate. In some examples, the nanoparticles are dielectrics that are suspended in a ceramic matrix.

A surface of the first conduction layer 202A is electrically coupled to the plasma-sonic layer 204 along an interface in a transverse direction (e.g., x-y plane). This configuration facilitates capturing the oscillation of charged carriers (e.g., electrons, holes, etc.) of the nanoparticles in the plasma-sonic layer 204 at the first conduction layer 202A to generate an alternating electric current along the first conduction layer 202A. Likewise, a surface of the second conduction layer 202B is electrically coupled to the plasma-sonic layer 204 along an interface in a transverse direction (e.g., x-y plane). This configuration facilitates capturing the oscillation of charged carriers (e.g., electrons, holes, etc.) of the nanoparticles in the plasma-sonic layer 204 at the second conduction layer 202B to generate an alternating electric current along the second conduction layer 202B, as depicted at test probe A.

In order to extract the charged carriers (e.g., electrons, holes, etc.) from the first conduction layer 202A and the second conduction layer 202B to charge the energy cell 106, rectifier bridge circuitry 220 is implemented to provide a same polarity of output with respect to reference ground for any input polarity (e.g., at a first input or second input). The first input of the rectifier bridge circuitry 220 is electrically coupled to the second conduction layer 202B and the second input of the rectifier bridge circuitry 220 is electrically coupled to the first conduction layer 202A. As depicted in FIG. 4A, a half-wave rectifier bridge 222 includes a first diode 226 connected in reverse bias across the second conduction layer 202B and a negative terminal (of the power collar 104 or the energy cell 106) and an optional second diode 227 is connected in reverse bias across the first conduction layer 202A and a positive terminal (of the power collar 104 or the energy cell 106). The half-wave rectifier bridge 222 of FIG. 4A coverts an AC power signal 410 at the input of the half-wave rectifier bridge 222 (at test probe A) from the plasma-sonic photovoltaic cell cross-section 200 to a pulsed DC power signal 412 at the output of the half-wave rectifier bridge 222 (at test probe B). In some examples, the energy cell 106 is electrically coupled across the output of the half-wave rectifier bridge 222 and the reference ground, thereby capturing and storing the oscillating charged carriers (e.g., electrons, holes, etc.) in the energy cell 106 for future use. In some configurations, the power collar 104 includes the rectifier bridge circuitry 220.

It should be appreciated that the rectifier bridge circuitry 220 can include one or more circuit elements to polarize the electric current. For example, the rectifier bridge circuitry 220 can be a full-wave rectifier bridge that includes four diodes interconnected so as to covert an AC power signal 410 (depicted at test probe A of FIG. 4B) of the plasma-sonic photovoltaic cell cross-section 200 to a pulsed DC power signal 412 (at test probe B of FIG. 4B). It should also be appreciated that capturing charged carriers (e.g., electrons, holes, etc.) along the surface of the nanoparticles for wavelengths of incident light longer than 700 nanometers causes a temperature of the first conduction layer 202A and the second conduction layer 202B to decrease because removing charged carriers (e.g., electrons, holes, etc.) from the plasma-sonic photovoltaic cell cross-section 200 extracts energy from the system that would otherwise contribute to heat. That is, removing oscillating charged carriers (e.g., electrons, holes, etc.) from the system slows down the overall motion of the molecules/atoms, which translates as reduced heat energy. This reduction of heat energy causes the adjacent layers that are thermally coupled to the first conduction layer 202A and the second conduction layer 202B to cool as well.

The plasma-sonic photovoltaic cell cross-section 225 depicted in FIG. 4B includes a first conduction layer 202A, a diode layer 208, a plasma-sonic layer 204, and a second conduction layer 202B. Both the first conductor layer 202A and the second conduction layer 202B can be made of a conductive material, such as metal, alloy, or a semiconductor (e.g., copper, aluminum, polysilicon, stainless steel, and the like). The first conductor layer 202A and/or the second conduction layer 202B can also made from a semimetal, such as graphene, arsenic, antimony, etc. In some examples, the first conductor layer 202A and/or the second conduction layer 202B is made from a semimetal (e.g., graphene, arsenic, antimony etc.) that is p-doped or n-doped. In some examples, the first conductor layer 202A and/or the second conduction layer 202B is made from conductive nanowires (e.g., metallic nanowires, semimetal nanowires, and doped semimetal nanowires) or nanotubes (e.g., carbon nanotubes). In some configurations, the first conduction layer 202A is electrically coupled to the second conduction layer 202B.

In some configurations, the rectifier bridge circuitry 220 includes one or more diodes electrically coupled in series between the first conductor layer 202A and cathode of the energy cell 106 and one or more diodes electrically coupled in series between the second conductor layer 202B and anode of the energy cell 106, as depicted in FIG. 4A. In some configurations, the rectifier bridge circuitry 220 includes one or more diode layers electrically coupled to the plasma-sonic layer 204. For example, as depicted in the plasma-sonic photovoltaic cell cross-section 225 of FIG. 4B, a diode layer 208 is electrically coupled between the plasma-sonic layer 204 and the second conductor layer 202B. The diode layer 208 is a semiconductor layer with a p-doped portion adjacent to an n-doped portion to form a p-n junction. The p-n junction effectively replaces the first diode 226 of the plasma-sonic photovoltaic cell cross-section 200 depicted in FIG. 4A.

In some configurations, the rectifier bridge circuitry 220 includes a first diode layer 208A electrically coupled between the plasma-sonic layer 204 and the first conductor layer 202A and a second diode layer 208B electrically coupled between the plasma-sonic layer 204 and the second conductor layer 202B (FIG. 4C). Both the first diode layer 208A and the second conductor layer 202B are semiconductor layers, each with a p-doped portion adjacent to an n-doped portion to form a p-n junction. As depicted in the plasma-sonic photovoltaic cell cross-section 250 of FIG. 4C, the p-n junction configuration of the first diode layer 208A effectively replaces the second diode 227 of the plasma-sonic photovoltaic cell cross-section 200 of FIG. 4A. As depicted in the plasma-sonic photovoltaic cell cross-section 250 of FIG. 4C, the p-n junction configuration of the second diode layer 208B effectively replaces the first diode 226 of the plasma-sonic photovoltaic cell cross-section 200 of FIG. 4A.

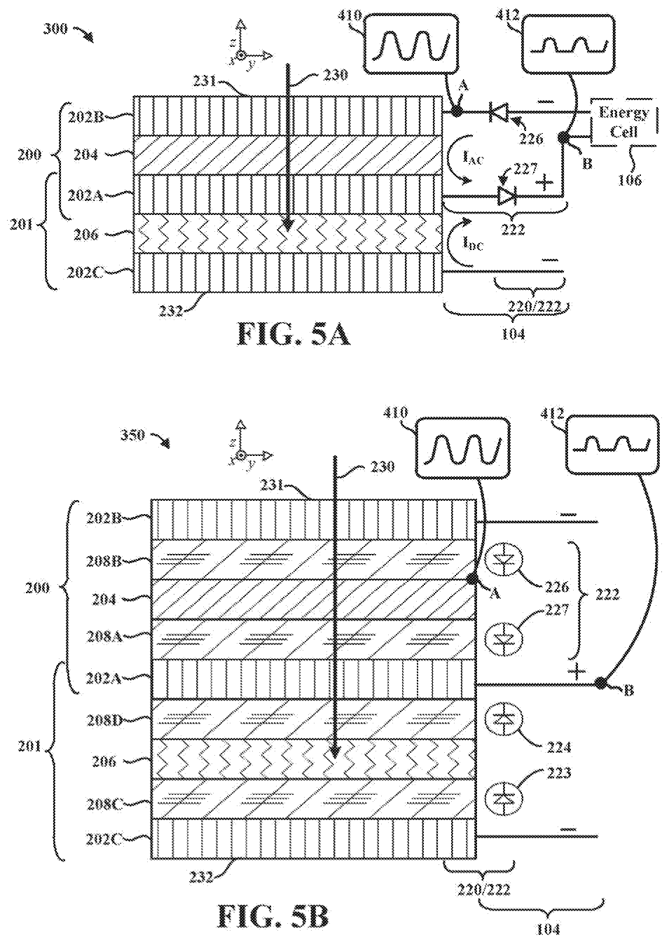

FIGS. 5A and 5B illustrate various cross-sectional views of exemplary hybrid plasma-sonic-based photovoltaic collectors. A hybrid plasma-sonic-based photovoltaic collector can include a plasma-sonic photovoltaic cell stacked (e.g., in parallel) with a photonic photovoltaic cell. For example, as depicted in FIG. 5A, the plasma-sonic photovoltaic cell cross-section 200 includes the plasma-sonic photovoltaic cell cross-section 200 (FIG. 4A) stacked (e.g., in parallel) with a photonic photovoltaic cell cross-section 201. The layout of the plasma-sonic photovoltaic cell cross-section 200 includes a first conduction layer 202A, a plasma-sonic layer 204, and a second conduction layer 202B as described supra.

The photonic photovoltaic cell cross-section 201 includes a photonic absorption layer 206 electrically coupled to the first conduction layer 202A and the third conduction layer 202C. As depicted in FIG. 5A, the photonic absorption layer 206 is electrically coupled between the first conduction layer 202A and the third conduction layer 202C along a transverse direction (e.g., x-y plane). The photonic absorption layer 206 is configured to absorb incident light 230 shorter than a first wavelength of incident light and generates a first electric current along the first conduction layer 202A. The absorption of incident light 230 shorter than a first wavelength of incident light generates electron-hole pairs, which induces a direct electric current (e.g., a first electric current) that flows though the photonic absorption layer 206 from the third conduction layer 202C to the first conduction layer 202A. In some examples, the first electric current is a direct current (e.g., loc).

In some configurations, the photonic absorption layer 206 is a semiconductor, such as silicon (polycrystalline silicon or monocrystalline silicon), germanium, cadmium telluride, copper indium gallium selenide, gallium arsenide (GaAs), indium gallium arsenide, and the like. In some configurations the photonic photovoltaic cell implements quantum dots. Quantum dots are nano-sized semiconductor particles that are proportional in size to the absorption wavelength of incident light and can have a variety of shapes. For example, one or more quantum dots can have any one of a conical, rectangular, bi-pyramidal, tetrahedral, cubical, octahedral, cylindrical, ellipsoidal, or spherical shape. Such quantum dots can be made from a variety of semiconducting materials, such as CdS, CdSe, Sb₂S₃, PbS, etc. In some examples, the photonic absorption layer 206 is an organic such as a ruthenium metalorganic dye. In general, the size of quantum dots in the photonic absorption layer 206 is proportional to the first wavelength of incident light. As such, the first wavelength of incident light can be can be tuned by increasing or decreasing the size of each quantum dot. In some examples, the first wavelength of incident light is tuned longer than 700 nanometers, which corresponds to frequencies in the infrared spectrum. In some examples, the first wavelength is tuned shorter than 700 nanometers, which corresponds to frequencies in the visible light and ultra-violet spectrum.

As depicted in FIG. 5A, the surface of the plasma-sonic layer 204 is electrically coupled between the first conduction layer 202A and the second conduction layer 202B along an interface in a transverse direction (e.g., x-y plane). The plasma-sonic layer 204 can be made from an electrical insulator, a dielectric, or a semiconductor. The plasma-sonic layer 204 can be a polymer or a ceramic. The plasma-sonic layer 204 can be polycarbonate. In general, the plasma-sonic layer 204 is non-conductive to direct current (e.g., I_{DC}) but is conductive to alternating current (e.g., I_{AC}). As such, plasma-sonic layer 204 is configured to be polarized in the presence of an electric field. This polarization causes positive charges to be displaced toward the electric field and negative charges to be displaced away from the electric field, which creates an internal electric field thereby reducing the overall electric field within the dielectric itself. The plasma-sonic layer 204 includes nanoparticles that couple with the polarization of the dielectric and induce charged carriers (e.g. electrons) to oscillate at a surface of the nanoparticles within the dielectric for certain wavelengths of incident light. It should be appreciated that the induced electron oscillations occur throughout the dielectric and are not simply concentrated at an interface between the dielectric and an adjacent conduction layer (e.g., the first conduction layer 202A and the second conduction layer 202B). In some instances, the second wavelength of incident light is at a resonance wavelength of the oscillating charged carriers (e.g., electrons, holes, etc.).

The second wavelength of incident light that induces charged carriers (e.g., electrons, holes, etc.) to oscillate at a surface of the nanoparticles correlates with the size of the nanoparticles within the plasma-sonic layer 204. As such, the second wavelength of incident light can be tuned by increasing or decreasing the size of the nanoparticles within plasma-sonic layer 204. In some examples, the wavelength is tuned longer than 700 nanometers, which corresponds to frequencies in the infrared spectrum. In some examples, the second wavelength of incident light is tuned shorter than 700 nanometers, which corresponds to frequencies in the visible light and ultra-violet spectrum. In some examples, the first wavelength of the incident light is tuned longer than the second wavelength of the incident light. In some examples, the first wavelength of the incident light is tuned shorter than the second wavelength of the incident light.

In some examples, the plasma-sonic layer 204 is an electrical insulator. In some examples, the plasma-sonic layer 204 is a dielectric with a complex dielectric constant. In some examples, the nanoparticles contribute to the plasma-sonic layer 204 having a complex dielectric constant. The nanoparticles within the plasma-sonic layer 204 can be homogenously dispersed (e.g., mixed) throughout the plasma-sonic layer 204 and can be a dielectric, a semiconductor, a semimetal, or a metal. The shape of the nanoparticles can be substantially similar or vary. The shape can have any one of a conical, rectangular, bi-pyramidal, tetrahedral, cubical, octahedral, cylindrical, ellipsoidal, or spherical shape. In some examples, the dielectric nanoparticles are dielectric particles suspended in a polymer matrix. In some examples, the dielectric nanoparticles are dielectric particles suspended in a polycarbonate. In some examples, the dielectric nanoparticles are dielectric particles suspended in a ceramic matrix.

As depicted in FIG. 5A, the surface of the second conduction layer 202B is electrically coupled to the plasma-sonic layer 204 along an interface in a transverse direction (e.g., x-y plane). This configuration facilitates capturing the oscillation of charged carriers (e.g., electrons, holes, etc.) of the nanoparticles in the plasma-sonic layer 204 at the second conduction layer 202B to generate a second electric current along the second conduction layer 202B. In some examples, the second electric current is an alternating current (e.g., I_{AC}), as depicted at test probe A in FIG. 5A.

In order to extract the charged carriers (e.g., electrons, holes, etc) from the second conduction layer 202B to charge the energy cell 106, a rectifier bridge circuitry 220 is implemented to provide a same polarity of output of the rectifier bridge circuitry 220 with respect to reference ground for any input polarity (e.g., at a first input or second input). The first input of the rectifier bridge circuitry 220 is electrically coupled to the second conduction layer 202B, and the second input of the rectifier bridge circuitry 220 is electrically coupled to the first conduction layer 202A. Notably, a pulsed direct current (e.g., I_{DC}) is provided at an output of the rectifier bridge circuitry 220 (e.g., at test probe B). As depicted in FIG. 5A, the first conduction layer 202A is electrically coupled to an input of the rectifier bridge circuitry 220.

As depicted in FIG. 5A, a half-wave rectifier bridge 222 includes a first diode 226 connected in reverse bias across the second conduction layer 202B and a negative terminal (of the power collar 104 or the energy cell 106) and an optional second diode 227 connected in reverse bias across the first conduction layer 202A and a positive terminal (of the power collar 104 or the energy cell 106). The half-wave rectifier bridge 222 of FIG. 4A coverts an AC power signal 410 at the input of the half-wave rectifier bridge 222 (at test probe A) from the plasma-sonic photovoltaic cell cross-section 200 to a pulsed DC power signal 412 at the output of the half-wave rectifier bridge 222 (at test probe B). In some examples, the energy cell 106 is electrically coupled across the output of the half-wave rectifier bridge 222 and the reference ground, thereby capturing and storing the oscillating charged carriers (e.g., electrons, holes, etc.) in the energy cell 106 for future use.

It should be appreciated that the half-wave rectifier bridge 222 can be a full-wave rectifier bridge that includes four diodes interconnected so as to covert an AC power signal 410 (depicted at test probe A of FIG. 5A) from the hybrid plasma-sonic photovoltaic cell cross-section 300 to a pulsed DC power signal 412. It should also be appreciated that capturing charged carriers (e.g., electrons, holes, etc.) along the surface of the nanoparticles for wavelengths of incident light longer than 700 nanometers causes a temperature of the first conduction layer 202A and the second conduction layer 202B to decrease because removing charged carriers (e.g., electrons, holes, etc.) from the plasma-sonic photovoltaic cell cross-section 200 extracts energy from the system that would otherwise contribute to heat. That is, removing oscillating charged carriers (e.g., electrons, holes, etc.) from the system slows down the overall motion of the molecules/atoms, which translates as reduced heat energy. This reduction of heat energy causes the adjacent layers that are thermally coupled to the first conduction layer 202A and the second conduction layer 202B to cool as well. In this instance, the photonic absorption layer 206 is thermally coupled to the second conduction layer 202B (via the plasma-sonic layer 204) and causes the photonic absorption layer 206 to cool. The cooling of the photonic absorption layer 206 by the second conduction layer 202B increases the efficiency of the photonic absorption layer 206 since the quantum efficiency increases with lower temperature.

In general, the second conduction layer 202B and the plasma-sonic layer 204 are translucent or transparent to wavelengths longer than 700 nanometers, thereby providing an optical path for incident light 230 to be absorbed by the photonic absorption layer 206. As such, both the direct current (e.g., a first electric current, I_{DC}) from the electron-hole generations of the photonic absorption layer 206 and the alternating current (e.g., second electric current, I_{AC}) captured from the oscillating charged carriers (e.g., electrons, holes, etc.) from the current plasma-sonic layer 204 can provide electrical energy to the energy cell 106 in parallel with each other.

In some examples, each layer (e.g., the second conduction layer 202B, the plasma-sonic layer 204, and the photonic absorption layer 206, etc.) are translucent or transparent to the incident light within the visible spectrum (e.g., 390 nanometers to 700 nanometers) at a zero degree incident angle. In some examples, a combination of each layer (e.g., the second conduction layer 202B, the plasma-sonic layer 204, and the photonic absorption layer 206, etc.) has a transmittance of light within the visible spectrum greater than 0.76 at a zero degree incident angle. In some examples, the photonic absorption layer 206 includes light scattering particles. In some examples, currents (e.g., a first electric current and second electric current) are superimposed.

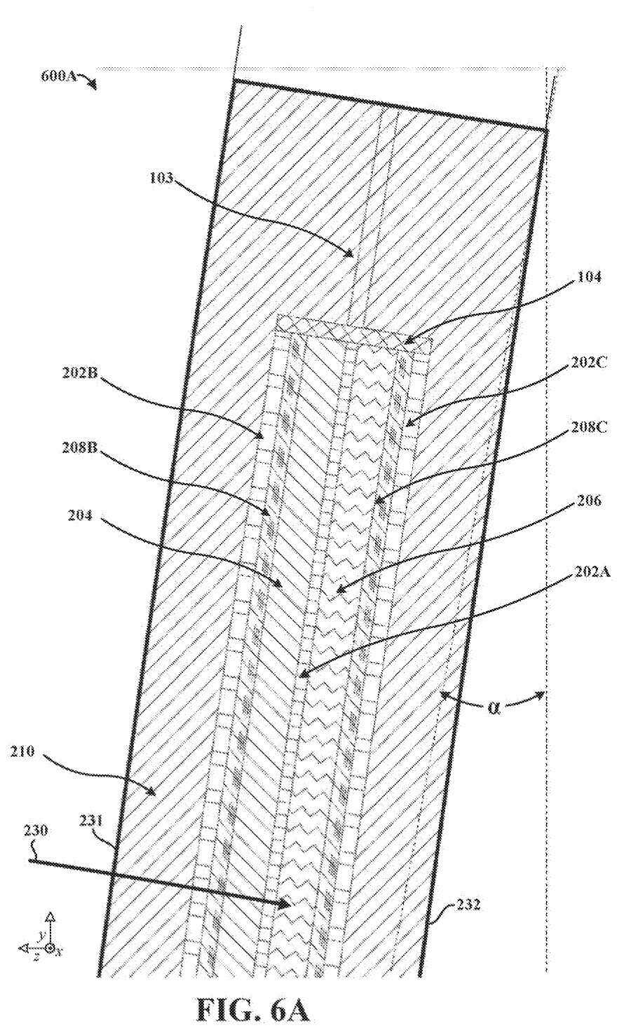

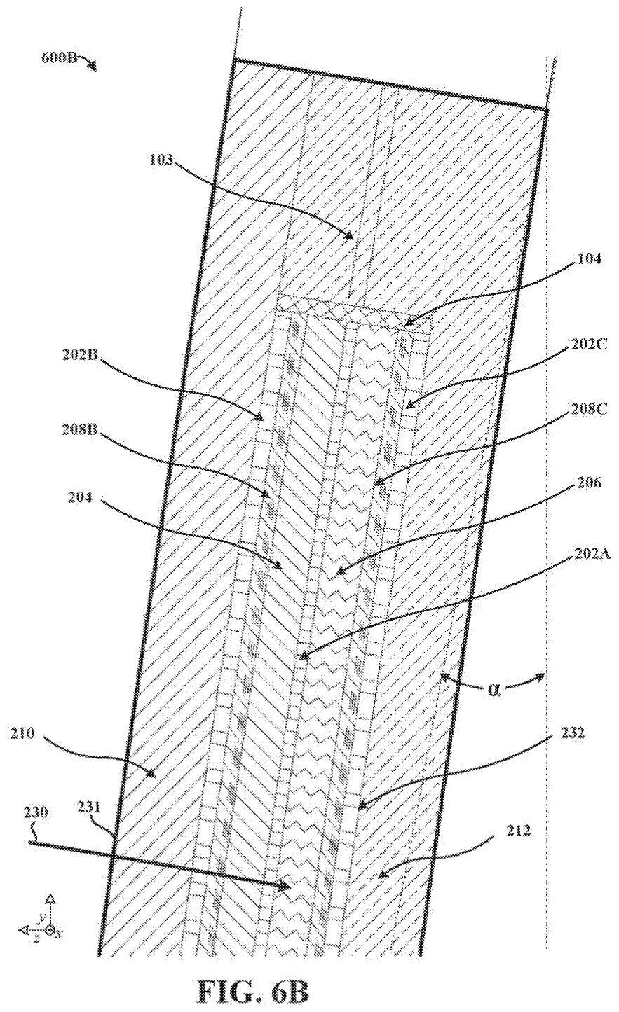

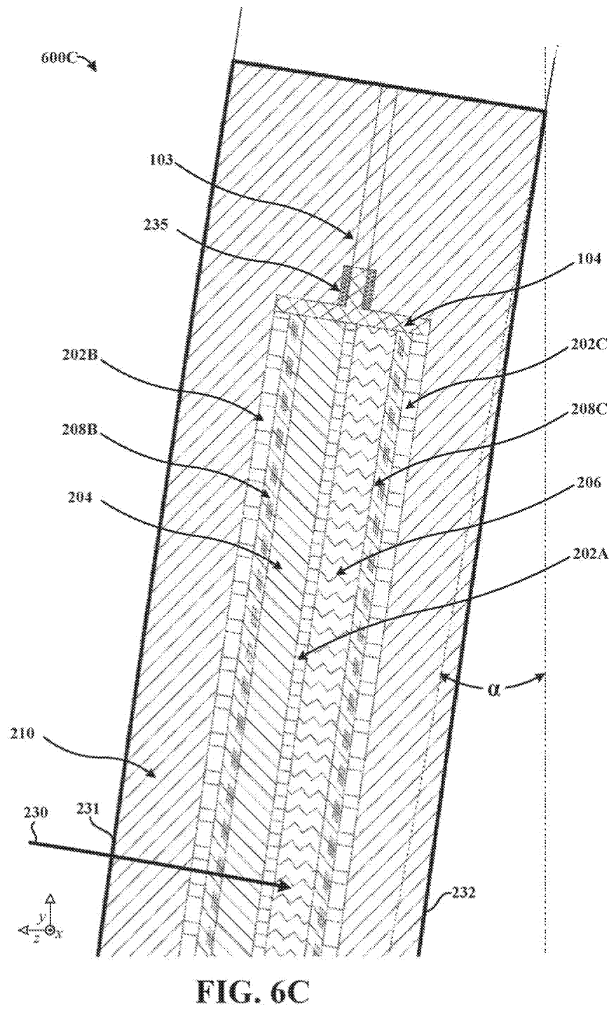

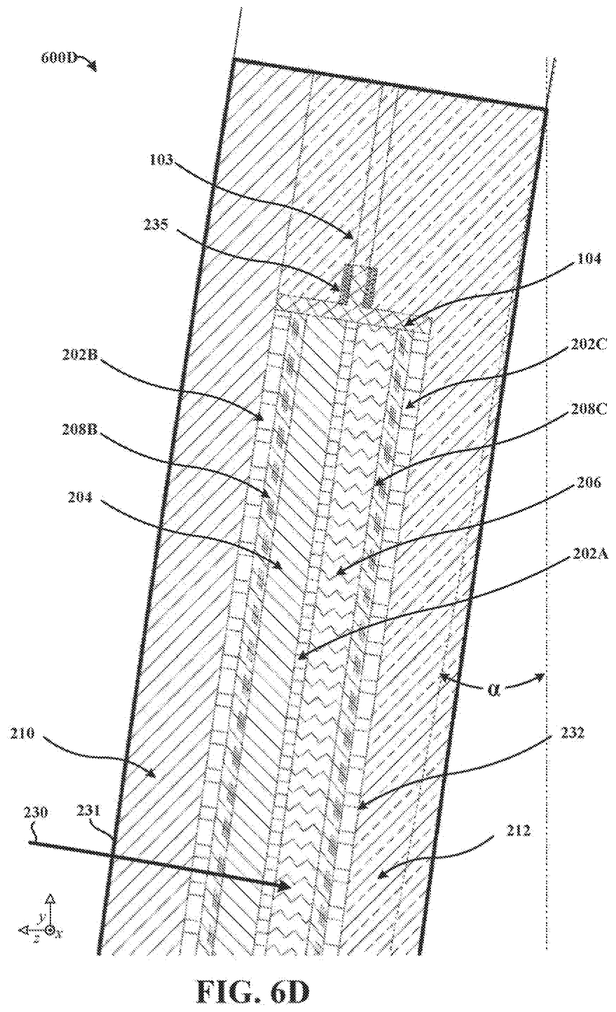

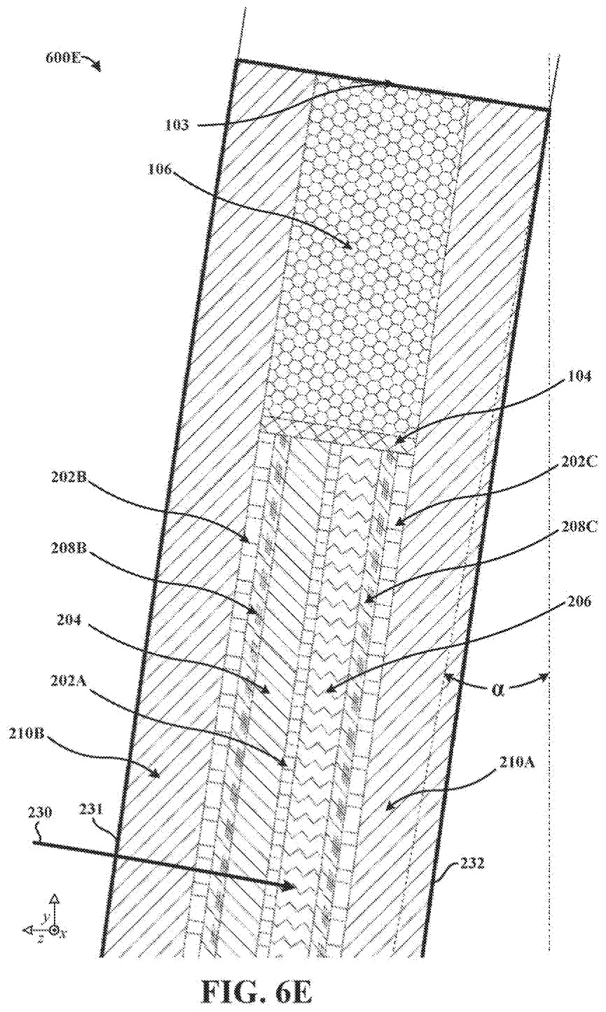

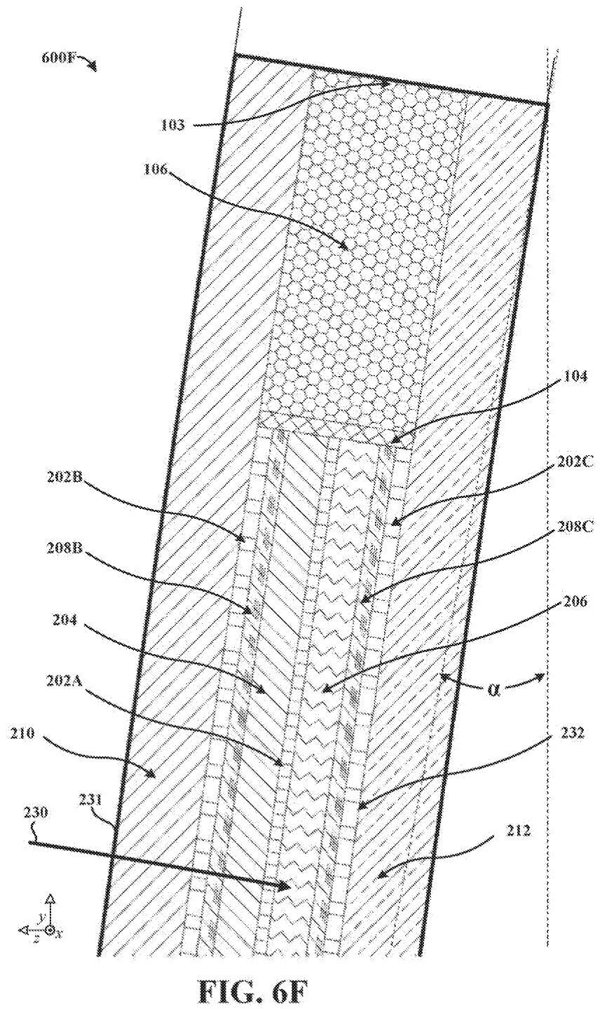

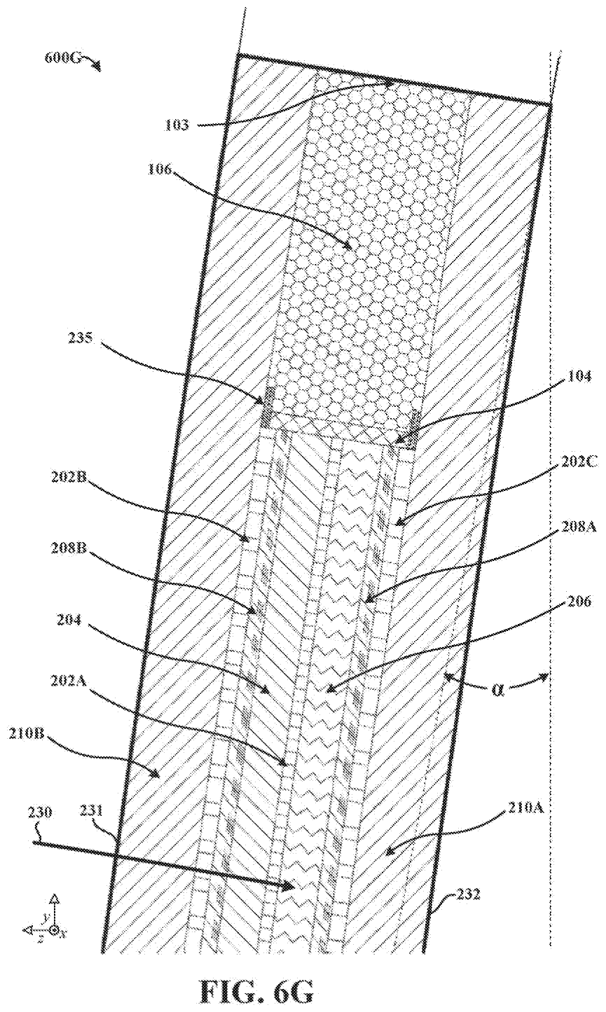

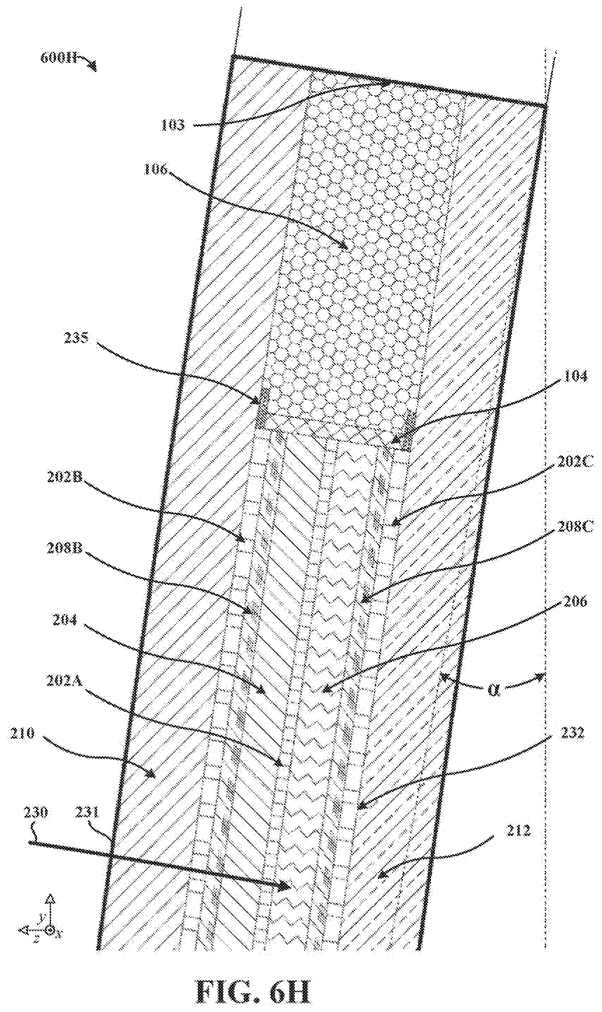

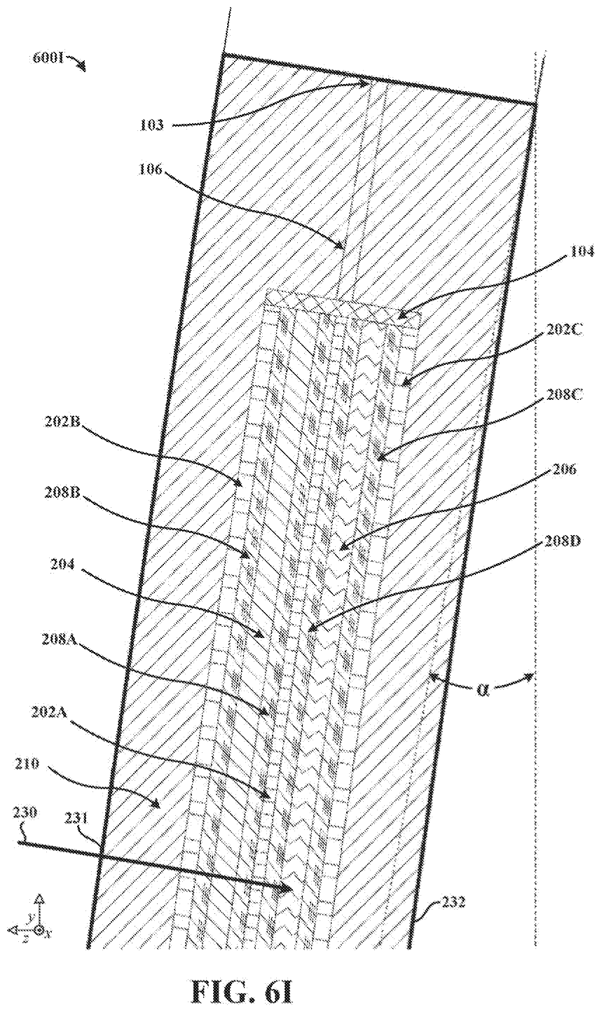

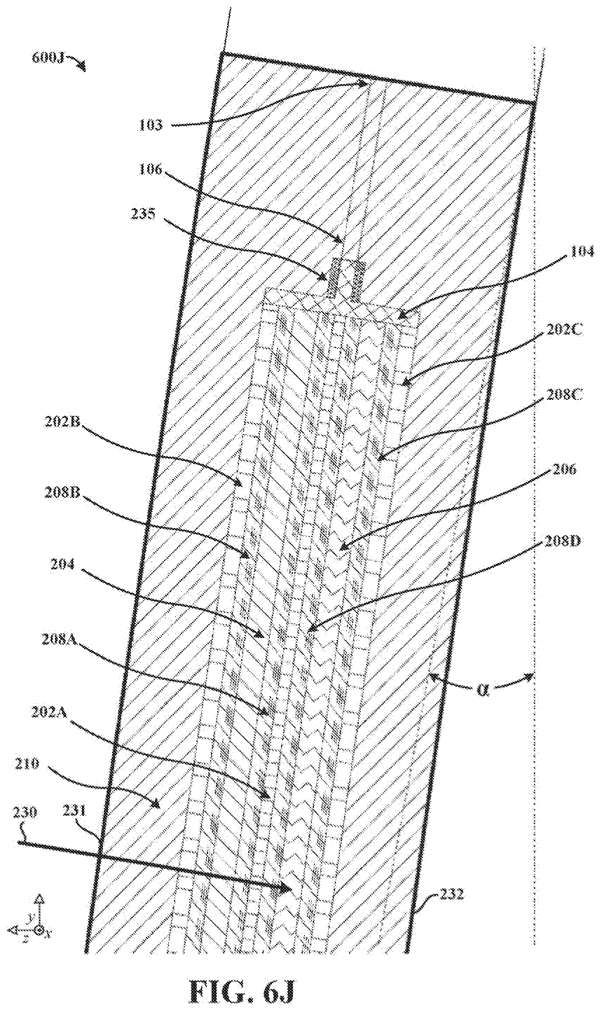

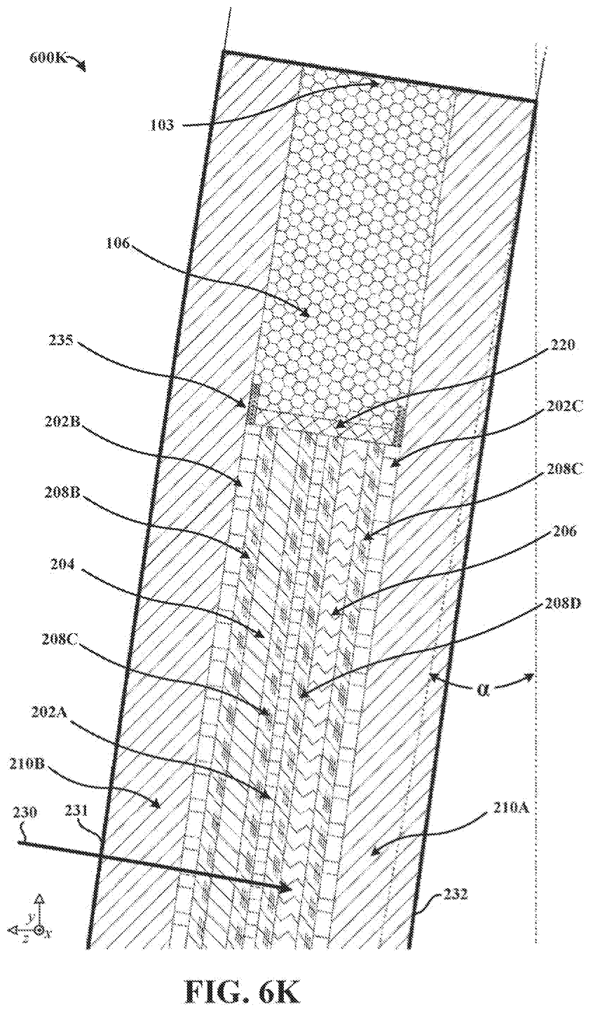

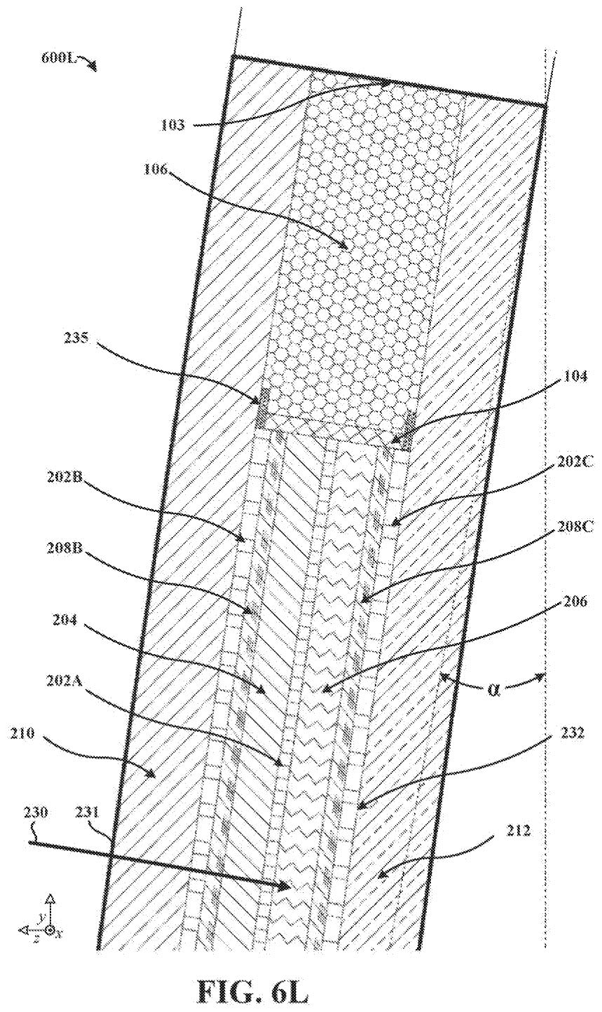

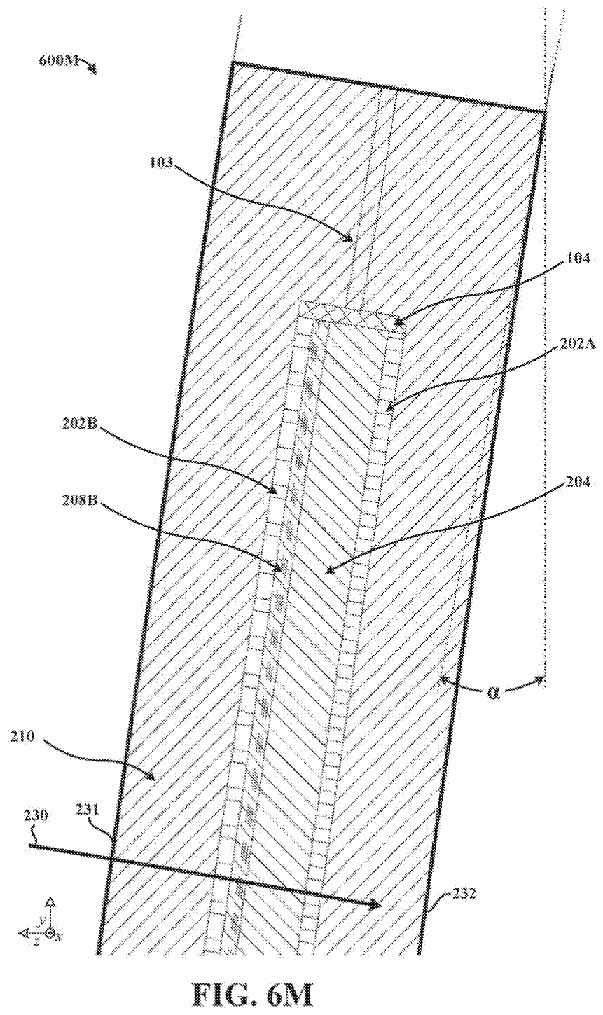

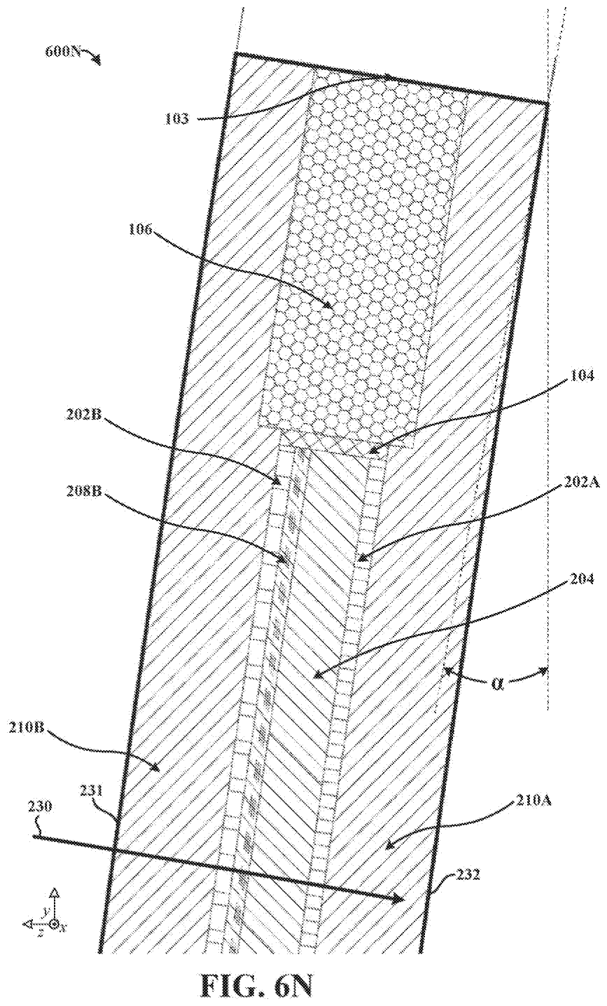

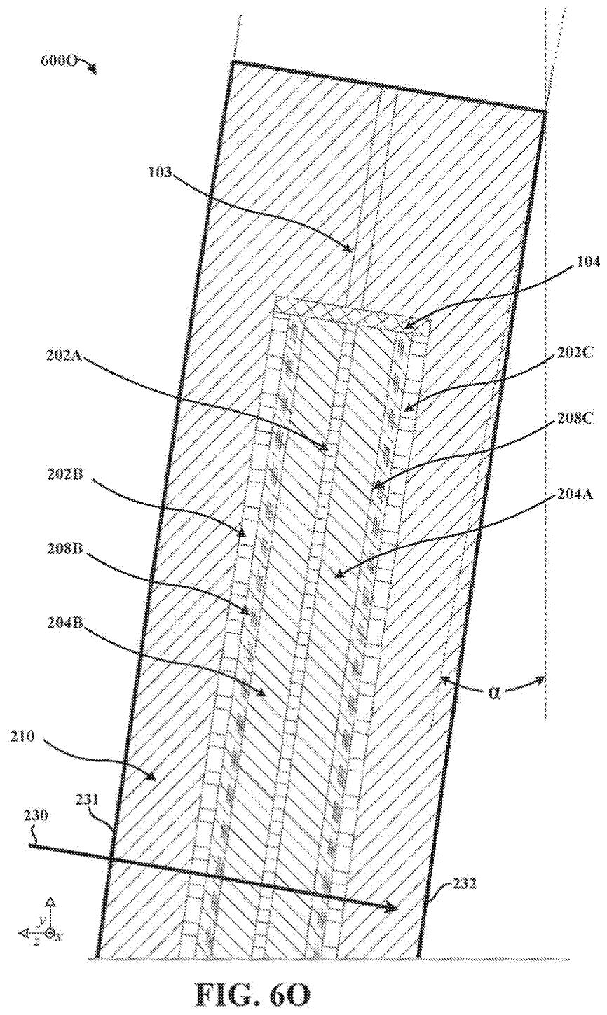

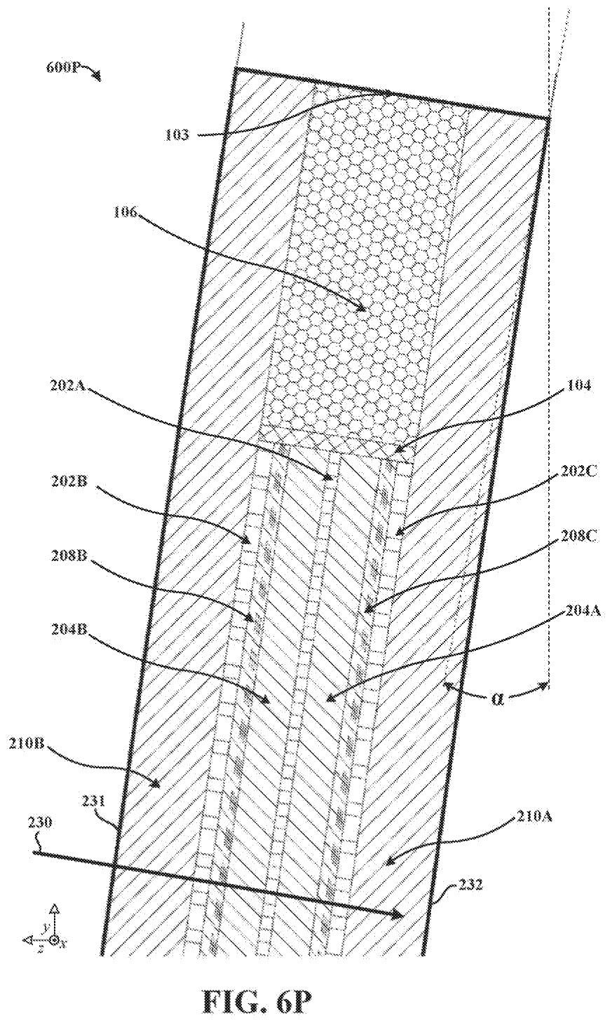

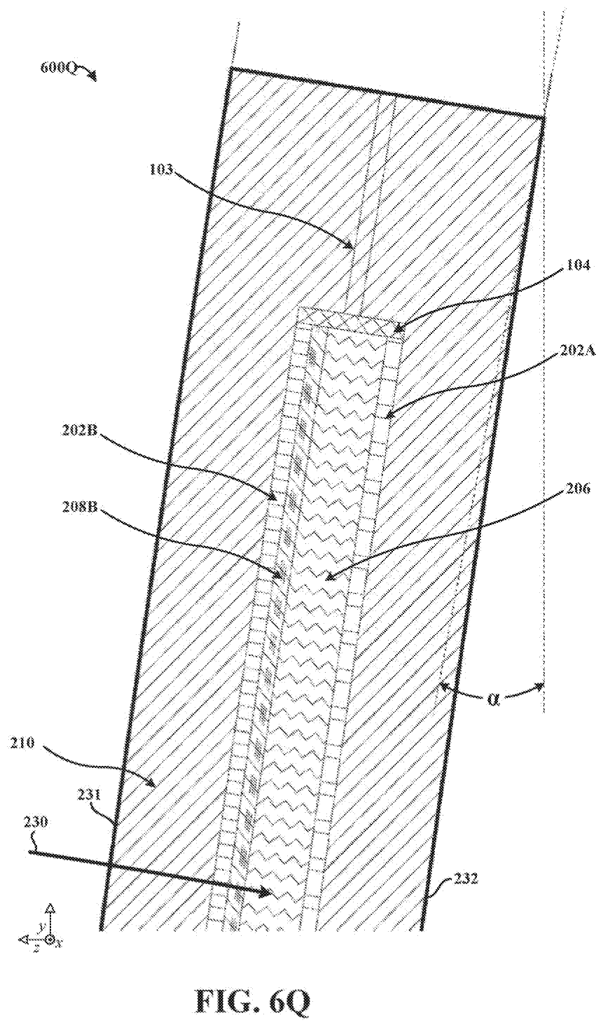

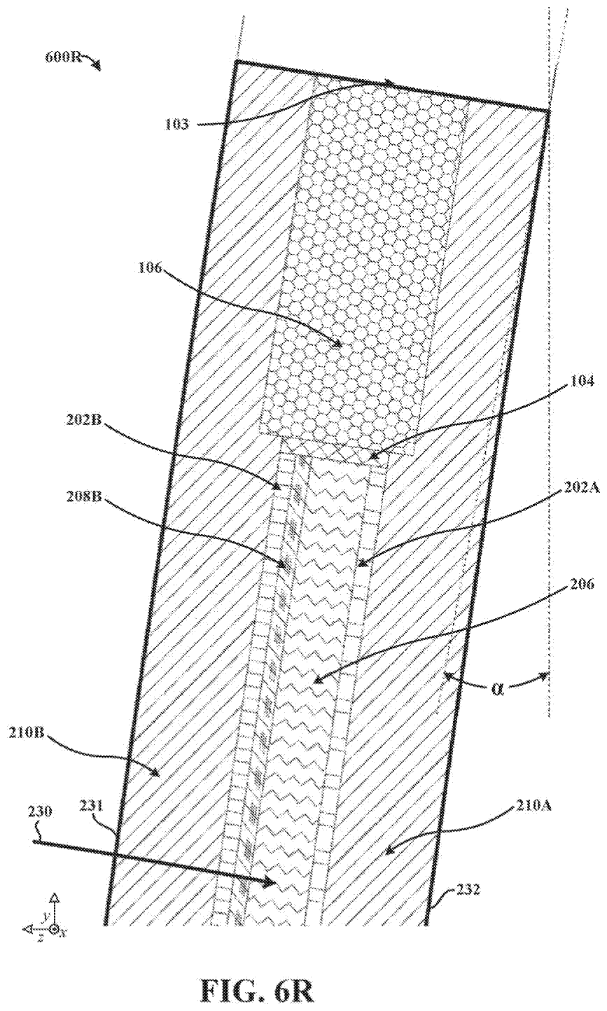

In some examples, one or more translucent layers are provided as a substrate around the first conduction layer 202A, the photonic absorption layer 206, the plasma-sonic layer 204, and the second conduction layer 202B (FIGS. 6A-6R). In some configurations, the one or more translucent layers are configured to hermetically seal the third conduction layer 202C, the photonic absorption layer 206, the first conduction layer 202A, the plasma-sonic layer 204, and the second conduction layer 202B. In some examples, a reflector is provided adjacent the third conduction layer 202A on a distal surface 232 of incident light 230. In such a configuration, the reflector is configured to reflect incident light 230 back through the third conduction layer 202C, the photonic absorption layer 206, the first conduction layer 202A, the plasma-sonic layer 204, and the second conduction layer 202B to increase chances of absorption and increase induced charged carriers (e.g., electrons, holes, etc.) oscillations at a surface of the nanoparticles. The reflector can be made from a metal, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

In some configurations, the half-wave rectifier bridge 222 includes a first diode layer 208A electrically coupled between the plasma-sonic layer 204 and the first conductor layer 202A. For example, as depicted in the enhanced hybrid plasma-sonic photovoltaic cell cross-section 350 of FIG. 5B, the p-n junction configuration of the first diode layer 208A effectively replaces the second diode 227 of the hybrid plasma-sonic photovoltaic cell cross-section 300 of FIG. 5A. In such a configuration, the first diode layer 208A is configured to direct charged carriers (e.g., electrons, holes, etc.) to be captured by the first conducting layer 202A. In some configurations, the half-wave rectifier bridge 222 includes a second diode layer 208B electrically coupled between the plasma-sonic layer 204 and the second conductor layer 202B. For examples, as depicted in the enhanced hybrid plasma-sonic photovoltaic cell cross-section 350 of FIG. 5B, the p-n junction configuration of the second diode layer 208B effectively replaces the first diode 226 of the hybrid plasma-sonic photovoltaic cell cross-section 300 of FIG. 5A. In such a configuration, the second diode layer 208B is configured to direct charged carriers (e.g., electrons, holes, etc.) to be captured by the second conducting layer 202B. Both the first diode layer 208A and the second conductor layer 202B are semiconductor layers, each with a p-doped portion adjacent to an n-doped portion to form a p-n junction.

In some configurations, photonic photovoltaic cell cross-section 201 includes a third diode layer 208C electrically coupled between the photonic absorption layer 206 and the third conductor layer 202C. The third diode layer 208C is a semiconductor layer with a p-doped portion adjacent to an ti-doped portion to form a p-n junction. As depicted in FIG. 5B, the third diode layer 208C essentially forms a third diode 223 in reverse bias across third conduction layer 202C and the photonic absorption layer 206. In such a reverse bias configuration, the built-in potential of the p-n junction of the third diode layer 208C directs charged carriers (e.g., electrons, holes, etc.) to be captured by the third conducting layer 202C.

In some configurations, photonic photovoltaic cell cross-section 201 includes a fourth diode layer 208D electrically coupled between the photonic absorption layer 206 and the first conductor layer 202A. The fourth diode layer 208D is a semiconductor layer with a p-doped portion adjacent to an n-doped portion to form a p-n junction. As depicted in FIG. 5B, the fourth diode layer 208D essentially forms a fourth diode 224 in reverse bias across first conduction layer 202A and the photonic absorption layer 206. In such a reverse bias configuration, the built-in potential of the p-n junction of the fourth diode layer 208D directs charged carriers (e.g., electrons, holes, etc.) to be captured by the first conducting layer 202A.

In general, the second conduction layer 202B, the second diode layer 208B, the plasma-sonic layer 204, and the first diode layer 208A are translucent or transparent to wavelengths longer than 700 nanometers, thereby providing an optical path for incident light 230 to be absorbed by the photonic absorption layer 206. As such, both the direct current (e.g., a first electric current, I_{DC}) from the electron-hole generations of the photonic absorption layer 206 and the alternating current (e.g., second electric current, I_{AC}) captured from the oscillating charged carriers (e.g., electrons, holes, etc.) in current plasma-sonic layer 204 can provide electrical energy to the energy cell 106 in parallel with each other.

In some examples, each layer (e.g., the second conduction layer 202B, the second diode layer 208B, the plasma-sonic layer 204, the first diode layer 208A, the first conduction layer 202A, the fourth diode layer 208D, the photonic absorption layer 206, the third diode layer 208C, and the third conduction layer 202C, etc.) are translucent or transparent to the incident light within the visible spectrum (e.g., 390 nanometers to 700 nanometers) at a zero degree incident angle. In some examples, a combination of each layer (e.g., the second conduction layer 202B, the second diode layer 208B, the plasma-sonic layer 204, the first diode layer 208A, the first conduction layer 202A, the fourth diode layer 208D, the photonic absorption layer 206, the third diode layer 208C, and the third conduction layer 202C, etc.) has a transmittance of light within the visible spectrum greater than 0.76 at a zero degree incident angle. In some examples, the photonic absorption layer 206 includes light-scattering particles. In some examples, currents (e.g., a first electric current and second electric current) are superimposed by having the second conduction layer 202B electrically coupled to the third conduction layer 202C.

In some examples, one or more translucent layers are provided as a substrate around the second conduction layer 202B, the second diode layer 208B, the plasma-sonic layer 204, the first diode layer 208A, the first conduction layer 202A, the fourth diode layer 208D, the photonic absorption layer 206, the third diode layer 208C, and the third conduction layer 202C, (FIGS. 6A-6R). In some configurations, the one or more translucent layers are configured to hermetically seal the second conduction layer 202B, the second diode layer 208B, the plasma-sonic layer 204, the first diode layer 208A, the first conduction layer 202A, the fourth diode layer 2081), the photonic absorption layer 206, the third diode layer 208C, and the third conduction layer 202C.

In some configurations, a reflector layer 212 is provided on a distal surface 232 of incident light 230. In such a configuration, the reflector layer 212 is configured to reflect incident light 230 back through the second conduction layer 202B, the second diode layer 208B, the plasma-sonic layer 204, the first diode layer 208A, the first conduction layer 202A, the fourth diode layer 208D, the photonic absorption layer 206, the third diode layer 208C, and the third conduction layer 202C to increase chances of absorption and increase induced charged carrier (e.g., electrons, holes, etc.) oscillations at a surface of the nanoparticles. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIGS. 6A-6R illustrate cross-sectional views of various plasma-sonic-based and/or photonic based photovoltaic collectors. A first enhanced hybrid plasma-sonic photovoltaic collector cross-section 600A depicted in FIG. 6A includes the translucent layer 210 surrounding the third conduction layer 202C, the third diode layer 208C, the photonic absorption layer 206, the first conduction layer 202A, the plasma-sonic layer 204, the second diode layer 208B, the second conduction layer 202B, the power collar 104, and interconnect traces 103. The first enhanced hybrid plasma-sonic photovoltaic collector cross-section 600A has a convex shape, where the photovoltaic collector is elongated toward an incident surface 231 of incident light 230, with a largest angle of curvature, α, at the edges of the photovoltaic collector.

The functionality of the first enhanced hybrid plasma-sonic photovoltaic collector cross-section 600A includes one or more layers of the enhanced hybrid plasma—sonic photovoltaic cell cross-section 350 (FIG. 5B), as described supra. The layers include the third conduction layer 202C, the third diode layer 208C, the photonic absorption layer 206, the first conduction layer 202A, the plasma-sonic layer 204, the second diode layer 208B, and the second conduction layer 202B. The interconnect traces 103 can be made from a conductive material, such as copper, aluminum, polysilicon, stainless steel, graphene, and the like. Portions of interconnect traces 103 are hermetically sealed within the translucent layer 210. The interconnect traces 103 are configured to provide electrical conduits to the anode of the power collar 104 and the cathode of the power collar 104. In some configurations, the interconnect traces 103 are connected to a socketing feature, such as a male or a female connector that is configured to connect (e.g., electrically couple) with adjacent photovoltaic collectors. In some configurations, the interconnect traces 103 are a part of the power collar 104.

Functional aspects of the rectifier bridge circuitry 220 are described supra. The rectifier bridge circuitry 220 can be hermetically sealed within the translucent layer 210 or can be electrically coupled external the translucent layer 210 via the interconnect traces 103. In some configurations, the rectifier bridge circuitry 220 is a full-wave rectifier. In some configurations, the rectifier bridge circuitry 220 is a half-wave rectifier 222 with one or more diodes, as depicted in any one of FIGS. 4A-4C.

The power collar 104 is situated around a periphery of the first enhanced hybrid plasma-sonic photovoltaic collector cross-section 600A. The power collar 104 is configured to direct charged carriers (e.g., electrons, holes, etc.) to an energy cell or inverter. The power collar 104 is made from semiconductor materials, such as silicon (polycrystalline silicon or monocrystalline silicon), germanium, cadmium telluride, copper indium gallium selenide, gallium arsenide (GaAs), indium gallium arsenide, and the like. In some configurations, the power collar 104 includes the rectifier bridge circuitry 220. In some configurations, the power collar 104 is configured to electrically couple with one or more adjacent photovoltaic collectors. For instance, the power collar 104 can include a male or a female socketing feature to connect (e.g., electrically couple) with adjacent photovoltaic collectors.

The translucent layer 210 envelop the third conduction layer 202C, the third diode layer 208C, the photonic absorption layer 206, the first conduction layer 202A, the plasma-sonic layer 204, the second diode layer 208B, and the second conduction layer 202B. The translucent layer 210 can optionally envelop or partially envelop the interconnect traces 10, the rectifier bridge circuitry 220, and the power collar 104.

The translucent layer 210 provides a hermetic seal to protect the photovoltaic cell from the elements (e.g., rain, snow, wind, dust, etc.). The translucent layer 210 also provides structural support to protect the photovoltaic cell from impact damage (e.g., hail, rocks, sand, etc.). The translucent layer 210 can be made from any material that is translucent or transparent to wavelength longer than 700 nanometers, thereby providing an optical path for incident light 230 in the infrared spectrum to be absorbed by the photonic absorption layer 206. The translucent layer 210 can be made from any material that is translucent or transparent to wavelength shorter than 700 nanometers, thereby providing an optical path for incident light 230 in the visible or ultraviolet spectrum to be absorbed by the photonic absorption layer 206. In some examples, the translucent layer 210 is made from any material that is translucent or transparent in regions that span portions of both the infrared, visible, and ultraviolet spectrum. In some examples, translucent layer 210 is a polymer or a ceramic.

In some example, the first enhanced hybrid plasma-sonic photovoltaic collector cross-section 600A is translucent or transparent such that some incident light 230 passes through the first enhanced hybrid plasma-sonic photovoltaic collector cross-section 600A and exits from a distal surface 232 of incident light 230.

FIG. 6B depicts a second enhanced hybrid plasma-sonic photovoltaic collector cross-section 600C that is a variant of the first enhanced hybrid plasma-sonic photovoltaic collector cross-section 600A. The second enhanced hybrid plasma-sonic photovoltaic collector cross-section 600B includes the translucent layer 210 adjacent the second conduction layer 202B along an incident surface 231 of incident light 230 and a reflector layer 212 provided adjacent the first conduction layer 202A along a distal surface 232 of incident light 230. The translucent layer 210 and the reflector layer 212 sandwich one or more layers of the enhanced hybrid plasma-sonic photovoltaic cell cross-section 350 (FIG. 5B), such as the third conduction layer 202C, the third diode layer 208C, the photonic absorption layer 206, the first conduction layer 202A, the plasma-sonic layer 204, the second diode layer 208B, the second conduction layer 202B, the power collar 104, and interconnect traces 103. One or more optional layers can be included, such as the third diode layer 208C, fourth diode layer 208D, etc. The functionality of the second enhanced hybrid plasma-sonic photovoltaic collector cross-section 600B includes one or more layers of the enhanced hybrid plasma-sonic photovoltaic cell cross-section 350, as described supra with respect to FIG. 5B and FIG. 6A. Functional aspects of additional layers, which can include the interconnect traces 103, the rectifier bridge circuitry 220, and the power collar 104, are also described supra with respect to FIG. 5B and FIG. 6A. The second enhanced hybrid plasma-sonic photovoltaic collector cross-section 600B has a convex shape, where the photovoltaic collector is elongated toward an incident surface 231 of incident light 230, with a largest angle of curvature, α, at the edges of the photovoltaic collector.

The reflector is 212 is configured to reflect incident light 230 back through the third conduction layer 202C, the third diode layer 208C, the photonic absorption layer 206, the first conduction layer 202A, the plasma-sonic layer 204, the second diode layer 208B, and the second conduction layer 202B to increase chances of absorption and increase induced charged carrier (e.g., electrons, holes, etc.) oscillations at a surface of the nanoparticles. In some configurations, the reflector layer 212 includes an electrical insulation layer to insulate the reflector layer 212 from the layers. In some configurations, the reflector layer 212 is made from a metal, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6C depicts a third enhanced hybrid plasma-sonic photovoltaic collector cross-section 600C that is a variant of the first enhanced hybrid plasma-sonic photovoltaic collector cross-section 600A. The third enhanced hybrid plasma-sonic photovoltaic collector cross-section 600C includes the translucent layer 210 surrounding the third conduction layer 202C, the third diode layer 208C, the photonic absorption layer 206, the first conduction layer 202A, the plasma-sonic layer 204, the second diode layer 208B, the second conduction layer 202B, the power collar 104, and interconnect traces 103. One or more optional layers can be included, such as the third diode layer 208C, fourth diode layer 208D, etc. The third enhanced hybrid plasma-sonic photovoltaic collector cross-section 600C has a convex shape, where the photovoltaic collector is elongated toward an incident surface 231 of incident light 230, with a largest angle of curvature, α, at the edges of the photovoltaic collector. The functionality of the third enhanced hybrid plasma-sonic photovoltaic collector cross-section 600C includes one or more layers of the enhanced hybrid plasma-sonic photovoltaic cell cross-section 350, as described supra with respect to FIG. 5B and FIG. 6A. Functional aspects of additional layers, which can include the interconnect traces 103, the rectifier bridge circuitry 220, and the power collar 104, are also described supra with respect to FIG. 5B and FIG. 6A.

The rectifier bridge circuitry 220 further includes light-emitting diodes (LEDs) 235. In some examples, the rectifier bridge circuitry 220 is configured to illuminate the LEDs 235 when the power is being delivered to the energy cell 106. In some examples, the rectifier bridge circuitry 220 is configured to illuminate the LEDs 235 when the power is not being delivered to the energy cell 106. In some examples, the rectifier bridge circuitry 220 is configured to illuminate the LEDs 235 at night as a backlight illumination to a building/structure/transportation/walkway. In some instances, the LEDs 235 are high intensity LEDs.

FIG. 6D depicts a fourth enhanced hybrid plasma-sonic photovoltaic collector cross-section 600D that is a variant of the first enhanced hybrid plasma-sonic photovoltaic collector cross-section 600A. The fourth enhanced hybrid plasma-sonic photovoltaic collector cross-section 600D includes the translucent layer 210 adjacent the second conduction layer 202B along an incident surface 231 of incident light 230 and a reflector layer 212 provided adjacent the first conduction layer 202A along a distal surface 232 of incident light 230.

The translucent layer 210 and the reflector layer 212 sandwich one or more layers of the enhanced hybrid plasma-sonic photovoltaic cell cross-section 350 (FIG. 5B), such as the third conduction layer 202C, the third diode layer 208C, the photonic absorption layer 206, the first conduction layer 202A, the plasma-sonic layer 204, the second diode layer 208B, the second conduction layer 202B, the power collar 104, and interconnect traces 103. One or more optional layers can be included, such as the third diode layer 208C, fourth diode layer 208D, etc. The fourth enhanced hybrid plasma-sonic photovoltaic collector cross-section 600D has a convex shape, where the photovoltaic collector is elongated toward an incident surface 231 of incident light 230, with a largest angle of curvature, a, at the edges of the photovoltaic collector. The functionality of the fourth enhanced hybrid plasma-sonic photovoltaic collector cross-section 600D includes one or more layers of the enhanced hybrid plasma-sonic photovoltaic cell cross-section 350, as described supra with respect to FIG. 58 and FIGS. 6A-6C. Functional aspects of additional layers, which can include the interconnect traces 103, the rectifier bridge circuitry 220, and the power collar 104, are also described supra with respect to FIG. 5B and FIGS. 6A-6C.

The reflector layer 212 is provided adjacent the first conduction layer 202A along a distal surface 232 of incident light 230. In such a configuration, the reflector layer 212 is configured to reflect incident light 230 back through the third conduction layer 202C, the third diode layer 208C, the photonic absorption layer 206, the first conduction layer 202A, the plasma-sonic layer 204, the second diode layer 208B, and the second conduction layer 202B to increase chances of absorption and increase induced charged carriers (e.g., electrons, holes, etc.) oscillations at a surface of the nanoparticles. In some configurations, the reflector layer 212 includes an electrical insulation layer to insulate the reflector layer 212 from the layers. In some configurations, the reflector layer 212 is made from a metal, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6E depicts a fifth enhanced hybrid plasma-sonic photovoltaic collector cross-section 600E that is a variant of the first enhanced hybrid plasma-sonic photovoltaic collector cross-section 600A. The fifth enhanced hybrid plasma-sonic photovoltaic collector cross-section 600E includes a first translucent layer 210A provided adjacent the first conduction layer 202A along a distal surface 232 of incident light 230 and a second translucent layer 210B adjacent the second conduction layer 202B along an incident surface 231 of incident light 230.

The first translucent layer 210A and the second translucent layer 210B sandwich one or more layers of the enhanced hybrid plasma-sonic photovoltaic cell cross-section 350 (FIG. 5B), such as the third conduction layer 202C, the third diode layer 208C, the photonic absorption layer 206, the first conduction layer 202A, the plasma-sonic layer 204, the second diode layer 208B, the second conduction layer 202B, the power collar 104, the interconnect traces 103, and the energy cell 106. One or more optional layers can be included, such as the third diode layer 208C, fourth diode layer 208D, etc. The fifth enhanced hybrid plasma-sonic photovoltaic collector cross-section 600E has a convex shape, where the photovoltaic collector is elongated toward an incident surface 231 of incident light 230, with a largest angle of curvature, a, at the edges of the photovoltaic collector. The functionality of the fifth enhanced hybrid plasma-sonic photovoltaic collector cross-section 600E includes one or more layers of the enhanced hybrid plasma-sonic photovoltaic cell cross-section 350 (FIG. 5B), as described supra with respect to FIG. 5B and FIGS. 6A-6D. Functional aspects of additional layers, which can include the rectifier bridge circuitry 220 and the power collar 104, are also described supra with respect to FIG. 5B and FIGS. 6A-6D.

As depicted in FIG. 6E, the energy cell 106 is situated adjacent the rectifier bridge circuitry 220 or the power collar 104 of the fifth enhanced hybrid plasma-sonic photovoltaic collector cross-section 500E. The energy cell 106 can be a battery (e.g., a li-ion polymer battery) or a capacitor capable of storing a charge and provides a low impedance path to the alternating current (e.g., I_{AC}) thereby cancelling cyclical charges. The fifth enhanced hybrid plasma-sonic photovoltaic collector cross-section 600E has a convex shape, where the photovoltaic collector is elongated toward an incident surface 231 of incident light 230, with a largest angle of curvature, a, at the edges of the photovoltaic collector.

FIG. 6F depicts a sixth enhanced hybrid plasma-sonic photovoltaic collector cross-section 600F that is a variant of the first enhanced hybrid plasma-sonic photovoltaic collector cross-section 600A and includes aspects of the second enhanced hybrid plasma-sonic photovoltaic collector cross-section 600B and the fifth enhanced hybrid plasma-sonic photovoltaic collector cross-section 600E. The sixth enhanced hybrid plasma-sonic photovoltaic collector cross-section 600F includes a reflector layer 212 provided adjacent the third conduction layer 202C along a distal surface 232 of incident light 230 and a translucent layer 210 adjacent the second conduction layer 202B along incident surface 231 of incident light 230.

The translucent layer 210 and the reflector layer 212 sandwich one or more layers of the enhanced hybrid plasma-sonic photovoltaic cell cross-section 350 (FIG. 58), such as the third conduction layer 202C, the third diode layer 208C, the photonic absorption layer 206, the first conduction layer 202A, the plasma-sonic layer 204, the second diode layer 208B, the second conduction layer 202B, the power collar 104, the interconnect traces 103, and the energy cell 106. One or more optional layers can be included, such as the third diode layer 208C, fourth diode layer 208D, etc. The sixth enhanced hybrid plasma-sonic photovoltaic collector cross-section 600F has a convex shape, where the photovoltaic collector is elongated toward an incident surface 231 of incident light 230, with a largest angle of curvature, a, at the edges of the photovoltaic collector. The functionality of the sixth enhanced hybrid plasma-sonic photovoltaic collector cross-section 600F includes one or more layers of the enhanced hybrid plasma-sonic photovoltaic cell cross-section 350, as described supra with respect to FIG. 5B and FIGS. 6A-6E. Functional aspects of additional layers, which can include the energy cell 106, the rectifier bridge circuitry 220, and the power collar 104, are also described supra with respect to FIG. 5B and FIGS. 6A-6E.

FIG. 6G depicts a seventh enhanced hybrid plasma-sonic photovoltaic collector cross-section 600G that is a variant of the first enhanced hybrid plasma-sonic photovoltaic collector cross-section 600A. The seventh enhanced hybrid plasma-sonic photovoltaic collector cross-section 600G includes a first translucent layer 210A provided adjacent the first conduction layer 202A along a distal surface 232 of incident light 230 and a second translucent layer 210B adjacent the second conduction layer 202B along incident surface 231 of incident light 230.

The first translucent layer 210A and the second translucent layer 210B sandwich one or more layers of the enhanced hybrid plasma-sonic photovoltaic cell cross-section 350 (FIG. 5B), such as the third conduction layer 202C, the third diode layer 208C, the photonic absorption layer 206, the first conduction layer 202A, the plasma-sonic layer 204, the second diode layer 208B, the second conduction layer 202B, the power collar 104, the interconnect traces 103, light emitting diodes (LEDs) 235, and the energy cell 106. One or more optional layers can be included, such as the third diode layer 208C, fourth diode layer 208D, etc. The seventh enhanced hybrid plasma-sonic photovoltaic collector cross-section 600G has a convex shape, where the photovoltaic collector is elongated toward an incident surface 231 of incident light 230, with a largest angle of curvature, c, at the edges of the photovoltaic collector. The functionality of the seventh enhanced hybrid plasma-sonic photovoltaic collector cross-section 600G includes one or more layers of the enhanced hybrid plasma-sonic photovoltaic cell cross-section 350, as described supra with respect to FIG. 5B and FIGS. 6A-6F. Functional aspects of additional layers, which can include the energy cell 106, the rectifier bridge circuitry 220, and the power collar 104, are also described supra with respect to FIG. 5B and FIGS. 6A-6F.

FIG. 6H depicts an eighth enhanced hybrid plasma-sonic photovoltaic collector cross-section 600H that is a variant of the first enhanced hybrid plasma-sonic photovoltaic collector cross-section 600A. The eighth enhanced hybrid plasma-sonic photovoltaic collector cross-section 600H includes a reflector layer 212 provided adjacent the first conduction layer 202A along a distal surface 232 of incident light 230 and a translucent layer 210 adjacent the second conduction layer 202B along an incident surface 231 of incident light 230.

The reflector layer 212 and the translucent layer 210 sandwich one or more layers of the enhanced hybrid plasma-sonic photovoltaic cell cross-section 350 (FIG. 5B), such as the third conduction layer 202C, the third diode layer 208C, the photonic absorption layer 206, the first conduction layer 202A, the plasma-sonic layer 204, the second diode layer 208B, the second conduction layer 202B, the power collar 104, the interconnect traces 103, LEDs 235, and the energy cell 106. One or more optional layers can be included, such as the third diode layer 208C, fourth diode layer 208D, etc. The eighth enhanced hybrid plasma-sonic photovoltaic collector cross-section 600H has a convex shape, where the photovoltaic collector is elongated toward an incident surface 231 of incident light 230, with a largest angle of curvature, a, at the edges of the photovoltaic collector. The functionality of the eighth enhanced hybrid plasma-sonic photovoltaic collector cross-section 600H includes one or more layers of the enhanced hybrid plasma-sonic photovoltaic cell cross-section 350, as described supra with respect to FIG. 5B and FIGS. 6A-6G. Functional aspects of additional layers, which can include the energy cell 106, the rectifier bridge circuitry 220, and the power collar 104, are also described supra with respect to FIG. 5B and FIGS. 6A-6G.

FIG. 6I depicts a ninth enhanced hybrid plasma-sonic photovoltaic collector cross-section 600I that is a variant of the first enhanced hybrid plasma-sonic photovoltaic collector cross-section 600A. The ninth enhanced hybrid plasma-sonic photovoltaic collector cross-section 600I includes the translucent layer 210 surrounding one or more layers of the enhanced hybrid plasma-sonic photovoltaic cell cross-section 350 (FIG. 5B), such as the third conduction layer 202C, the third diode layer 208C, the photonic absorption layer 206, the fourth diode layer 208D, the first conduction layer 202A, the first diode layer 208A, the plasma-sonic layer 204, the second diode layer 208B, the second conduction layer 202B, the power collar 104, and the interconnect traces 103. The ninth enhanced hybrid plasma-sonic photovoltaic collector cross-section 600I has a convex shape, where the photovoltaic collector is elongated toward an incident surface 231 of incident light 230, with a largest angle of curvature, a, at the edges of the photovoltaic collector. The functionality of the ninth enhanced hybrid plasma-sonic photovoltaic collector cross-section 600I includes one or more layers of the enhanced hybrid plasma-sonic photovoltaic cell cross-section 350, as described supra with respect to FIG. 5B and FIGS. 6A-6H. Functional aspects of additional layers, which can include the interconnect traces 103, the rectifier bridge circuitry 220, and the power collar 104, are also described supra with respect to FIG. 5B and FIGS. 6A-6H.

FIG. 6J depicts a tenth enhanced hybrid plasma-sonic photovoltaic collector cross-section 600J that is a variant of the first enhanced hybrid plasma-sonic photovoltaic collector cross-section 600A. The tenth enhanced hybrid plasma-sonic photovoltaic collector cross-section 600J includes the translucent layer 210 surrounding one or more layers of the enhanced hybrid plasma-sonic photovoltaic cell cross-section 350 (FIG. 5B), such as the third conduction layer 202C, the third diode layer 208C, the photonic absorption layer 206, the fourth diode layer 208D, the first conduction layer 202A, the first diode layer 208A, the plasma-sonic layer 204, the second diode layer 208B, the second conduction layer 202B, the power collar 104, the light-emitting diodes (LEDs) 235, and the interconnect traces 103. The tenth enhanced hybrid plasma-sonic photovoltaic collector cross-section 600I has a convex shape, where the photovoltaic collector is elongated toward an incident surface 231 of incident light 230, with a largest angle of curvature, α, at the edges of the photovoltaic collector. The functionality of the tenth enhanced hybrid plasma-sonic photovoltaic collector cross-section 600J includes one or more layers of the enhanced hybrid plasma-sonic photovoltaic cell cross-section 350, as described supra with respect to FIG. 5B and FIGS. 6A-6I. Functional aspects of additional layers, which can include the interconnect traces 103, the rectifier bridge circuitry 220, and the power collar 104, are also described supra with respect to FIG. 5B and FIGS. 6A-6I.

FIG. 6K depicts an eleventh enhanced hybrid plasma-sonic photovoltaic collector cross-section 600K that is a variant of the first enhanced hybrid plasma-sonic photovoltaic collector cross-section 600A. The eleventh enhanced hybrid plasma-sonic photovoltaic collector cross-section 600K includes a first translucent layer 210A and a second translucent layer 210B that sandwich one or more layers of the enhanced hybrid plasma-sonic photovoltaic cell cross-section 350 (FIG. 5B), such as the third conduction layer 202C, the third diode layer 208C, the photonic absorption layer 206, the fourth diode layer 208D, the first conduction layer 202A, the first diode layer 208A, the plasma-sonic layer 204, the second diode layer 208B, the second conduction layer 202B, the power collar 104, energy cell 106, the LEDs 235, and the interconnect traces 103. The eleventh enhanced hybrid plasma-sonic photovoltaic collector cross-section 600K has a convex shape, where the photovoltaic collector is elongated toward an incident surface 231 of incident light 230, with a largest angle of curvature, a, at the edges of the photovoltaic collector. The functionality of the eleventh enhanced hybrid plasma-sonic photovoltaic collector cross-section 600K includes one or more layers of the enhanced hybrid plasma-sonic photovoltaic cell cross-section 350, as described supra with respect to FIG. 5B and FIGS. 6A-6J. Functional aspects of additional layers, which can include the energy cell 106, the rectifier bridge circuitry 220, and the power collar 104, are also described supra with respect to FIG. 5B and FIGS. 6A-6J.

FIG. 6L depicts a twelfth enhanced hybrid plasma-sonic photovoltaic collector cross-section 600L that is a variant of the first enhanced hybrid plasma-sonic photovoltaic collector cross-section 600A. The twelfth enhanced hybrid plasma-sonic photovoltaic collector cross-section 600L includes a reflector layer 212 provided adjacent the first conduction layer 202A along a distal surface 232 of incident light 230 and a translucent layer 210 adjacent the second conduction layer 202B along an incident surface 231 of incident light 230.

The reflector layer 212 and the translucent layer 210 sandwich one or more layers of the enhanced hybrid plasma-sonic photovoltaic cell cross-section 350 (FIG. 58), such as the third conduction layer 202C, the third diode layer 208C, the photonic absorption layer 206, the fourth diode layer 208D, the first conduction layer 202A, the first diode layer 208A, the plasma-sonic layer 204, the second diode layer 208B, the second conduction layer 202B, the power collar 104, energy cell 106, the light-emitting diodes (LEDs) 235, and the interconnect traces 103. The twelfth enhanced hybrid plasma-sonic photovoltaic collector cross-section 600L has a convex shape, where the photovoltaic collector is elongated toward an incident surface 231 of incident light 230, with a largest angle of curvature, α, at the edges of the photovoltaic collector. The functionality of the twelfth enhanced hybrid plasma-sonic photovoltaic collector cross-section 600L includes one or more layers of the enhanced hybrid plasma-sonic photovoltaic cell cross-section 350, as described supra with respect to FIG. 5B and FIGS. 6A-6K. Functional aspects of additional layers, which can include the energy cell 106, the rectifier bridge circuitry 220, and the power collar 104, are also described supra with respect to FIG. 5B and FIGS. 6A-6K.

FIG. 6M depicts a thirteenth enhanced hybrid plasma-sonic photovoltaic collector cross-section 600M that includes the translucent layer 210 that envelopes the first conduction layer 202A, the plasma-sonic layer 204, the second diode layer 208B, the second conduction layer 202B, the power collar 104, and the interconnect traces 103. The thirteenth enhanced hybrid plasma-sonic photovoltaic collector cross-section 600M has a convex shape, where the photovoltaic collector is elongated toward an incident surface 231 of incident light 230, with a largest angle of curvature, t, at the edges of the photovoltaic collector. The functionality of the thirteenth enhanced hybrid plasma-sonic photovoltaic collector cross-section 600M includes one or more layers of the enhanced hybrid plasma-sonic photovoltaic cell cross-section 350, as described supra with respect to FIG. 5B and FIGS. 6A-6L. Functional aspects of additional layers, which can include the interconnect traces 103, the rectifier bridge circuitry 220, and the power collar 104, are also described supra with respect to FIG. 5B and FIGS. 6A-6L.

In some configurations, the thirteenth enhanced hybrid plasma-sonic photovoltaic collector cross-section 600M includes a reflector layer 212 provided on a distal surface 232 of incident light 230. In such a configuration, the reflector layer 212 is configured to reflect incident light 230 back toward the surface of incident light the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6N depicts a fourteenth enhanced hybrid plasma-sonic photovoltaic collector cross-section 600N that includes the first translucent layer 210A and the second translucent layer 210B that sandwich one or more layers of the enhanced hybrid plasma-sonic photovoltaic cell cross-section 350 (FIG. 5B), such as the first conduction layer 202A, the plasma-sonic layer 204, the second diode layer 208B, the second conduction layer 202B, the power collar 104, the interconnect traces 103, and the energy cell 106. The fourteenth enhanced hybrid plasma-sonic photovoltaic collector cross-section 600N has a convex shape, where the photovoltaic collector is elongated toward an incident surface 231 of incident light 230, with a largest angle of curvature, a, at the edges of the photovoltaic collector. The functionality of the fourteenth enhanced hybrid plasma-sonic photovoltaic collector cross-section 600N includes one or more layers of the enhanced hybrid plasma-sonic photovoltaic cell cross-section 350, as described supra with respect to FIG. 5B and FIGS. 6A-6M. Functional aspects of additional layers, which can include the energy cell 106, the rectifier bridge circuitry 220, and the power collar 104, are also described supra with respect to FIG. 5B and FIGS. 6A-6M.

In some configurations, the fourteenth enhanced hybrid plasma-sonic photovoltaic collector cross-section 600N includes a reflector layer 212 provided on a distal surface 232 of incident light 230. In such a configuration, the reflector layer 212 is configured to reflect incident light 230 back toward the surface of incident light the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6O depicts a fifteenth enhanced hybrid plasma-sonic photovoltaic collector cross-section 600O that includes the translucent layer 210 that envelopes the third conduction layer 202C, third diode layer 208C, the first plasma-sonic layer 204A, the first conduction layer 202A, the plasma-sonic layer 204A, second the second diode layer 208A, the second conduction layer 202B, the power collar 104, and the interconnect traces 103. The fifteenth enhanced hybrid plasma-sonic photovoltaic collector cross-section 600O has a convex shape, where the photovoltaic collector is elongated toward an incident surface 231 of incident light 230, with a largest angle of curvature, a, at the edges of the photovoltaic collector. The functionality of the fifteenth enhanced hybrid plasma-sonic photovoltaic collector cross-section 600M includes one or more layers of the enhanced hybrid plasma-sonic photovoltaic cell cross-section 350, as described supra with respect to FIG. 5B and FIGS. 6A-6N. Functional aspects of additional layers, which can include the interconnect traces 103, the rectifier bridge circuitry 220, and the power collar 104, are also described supra with respect to FIG. 5B and FIGS. 6A-6N.

In some configurations, the fifteenth enhanced hybrid plasma-sonic photovoltaic collector cross-section 600O includes a reflector layer 212 provided on a distal surface 232 of incident light 230. In such a configuration, the reflector layer 212 is configured to reflect incident light 230 back toward the surface of incident light the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6P depicts a sixteenth enhanced hybrid plasma-sonic photovoltaic collector cross-section 600P that includes the translucent layer 210 that envelopes the third conduction layer 202C, third diode layer 208C, the first plasma-sonic layer 204A, the first conduction layer 202A, the plasma-sonic layer 204A, second the second diode layer 208A, the second conduction layer 202B, the power collar 104, the energy cell 106, and the interconnect traces 103. The sixteenth enhanced hybrid plasma-sonic photovoltaic collector cross-section 600P has a convex shape, where the photovoltaic collector is elongated toward an incident surface 231 of incident light 230, with a largest angle of curvature, a, at the edges of the photovoltaic collector. The functionality of the sixteenth enhanced hybrid plasma-sonic photovoltaic collector cross-section 600M includes one or more layers of the enhanced hybrid plasma-sonic photovoltaic cell cross-section 350, as described supra with respect to FIG. 5B and FIGS. 6A-6O. Functional aspects of additional layers, which can include the energy cell 106, the rectifier bridge circuitry 220, and the power collar 104, are also described supra with respect to FIG. 5B and FIGS. 6A-6O.

In some configurations, the sixteenth enhanced hybrid plasma-sonic photovoltaic collector cross-section 600P includes a reflector layer 212 provided on a distal surface 232 of incident light 230. In such a configuration, the reflector layer 212 is configured to reflect incident light 230 back toward the surface of incident light the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6Q depicts a seventeenth enhanced hybrid plasma-sonic photovoltaic collector cross-section 600Q that includes the translucent layer 210 that envelopes the first conduction layer 202A, the photonic absorption layer 206, the second diode layer 208B, the second conduction layer 202B, the power collar 104, and the interconnect traces 103. The seventeenth enhanced hybrid plasma-sonic photovoltaic collector cross-section 600Q has a convex shape, where the photovoltaic collector is elongated toward an incident surface 231 of incident light 230, with a largest angle of curvature, α, at the edges of the photovoltaic collector. The functionality of the seventeenth enhanced hybrid plasma-sonic photovoltaic collector cross-section 600Q includes one or more layers of the enhanced hybrid plasma-sonic photovoltaic cell cross-section 350, as described supra with respect to FIG. 5B and FIGS. 6A-6P. Functional aspects of additional layers, which can include the interconnect traces 103, the rectifier bridge circuitry 220, and the power collar 104, are also described supra with respect to FIG. 5B and FIGS. 6A-6P.

In some configurations, the seventeenth enhanced hybrid plasma-sonic photovoltaic collector cross-section 600Q includes a reflector layer 212 provided on a distal surface 232 of incident light 230. In such a configuration, the reflector layer 212 is configured to reflect incident light 230 back toward the surface of incident light the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

FIG. 6R depicts a eighteenth enhanced hybrid plasma-sonic photovoltaic collector cross-section 600R that includes the translucent layer 210 that includes a first translucent layer 210A provided adjacent the first conduction layer 202A along a distal surface 232 of incident light 230 and a second translucent layer 2101B adjacent the second conduction layer 202B along an incident surface 231 of incident light 230. The first translucent layer 210A and the second translucent layer 210B sandwich one or more layers of the enhanced hybrid plasma-sonic photovoltaic cell cross-section 350 (FIG. 5B), such as the first conduction layer 202A, the photonic absorption layer 206, the second diode layer 208B, the second conduction layer 202B, the power collar 104, the energy cell 106, and the interconnect traces 103. The eighteenth enhanced hybrid plasma-sonic photovoltaic collector cross-section 600R has a convex shape, where the photovoltaic collector is elongated toward an incident surface 231 of incident light 230, with a largest angle of curvature, a, at the edges of the photovoltaic collector. The functionality of the eighteenth enhanced hybrid plasma-sonic photovoltaic collector cross-section 600R includes one or more layers of the enhanced hybrid plasma-sonic photovoltaic cell cross-section 350, as described supra with respect to FIG. 5B and FIGS. 6A-6Q. Functional aspects of additional layers, which can include the interconnect traces 103, the rectifier bridge circuitry 220, and the power collar 104, are also described supra with respect to FIG. 5B and FIGS. 6A-6Q.

In some configurations, the eighteenth enhanced hybrid plasma-sonic photovoltaic collector cross-section 600R includes a reflector layer 212 provided on a distal surface 232 of incident light 230. In such a configuration, the reflector layer 212 is configured to reflect incident light 230 back toward the surface of incident light the photonic absorption layer 206 to increase chances of absorption. The reflector layer 212 can be a metal layer, such as aluminum, silver, gold, copper, etc. In some configurations, the reflector layer 212 is a composite material that includes a metal reflection layer. In some instances, the metal reflection layer is configured to reflect heat. In some examples, the reflector layer 212 is a thermal barrier. In some instances, the reflector layer 212 is a thermal insulator.

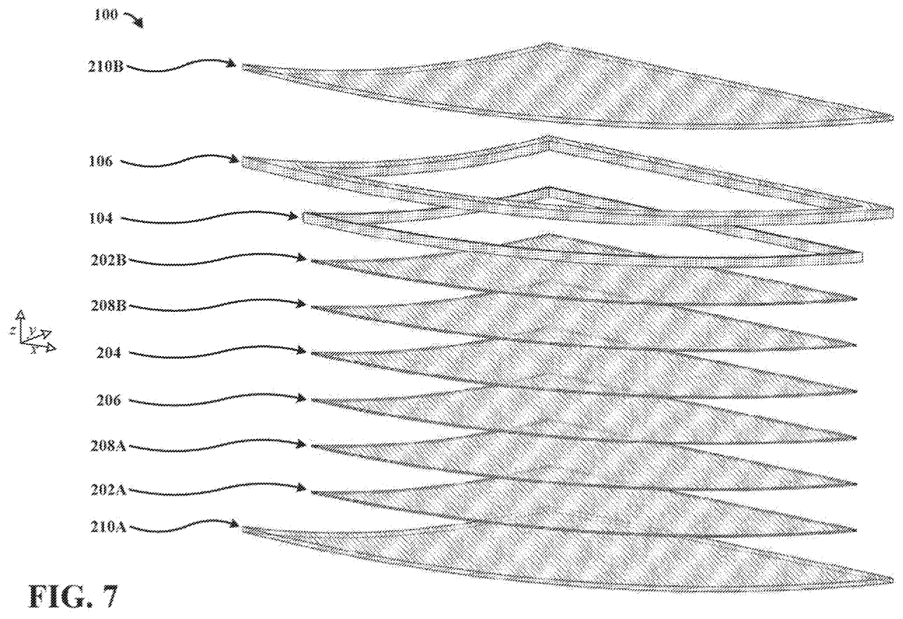

FIG. 7 illustrates an exploded view of exemplary plasma-sonic-based photovoltaic collector 100. The photovoltaic collector 100 includes a first translucent layer 210A, a first conduction layer 202A, a first diode layer 208A, a photonic absorption layer 206, a plasma-sonic layer 204, a second diode layer 208B, a second conduction layer 202B, a power collar 104, an energy cell 106, and a second translucent layer 210B. In this instance, the power collar 104 includes the rectifier bridge circuitry 220 to direct electrical power from the photonic absorption layer 206 and the plasma-sonic layer 204. Likewise, the energy cell 106 includes an anode and a cathode electrically coupled to the power collar 104 so as to store charge for later use.

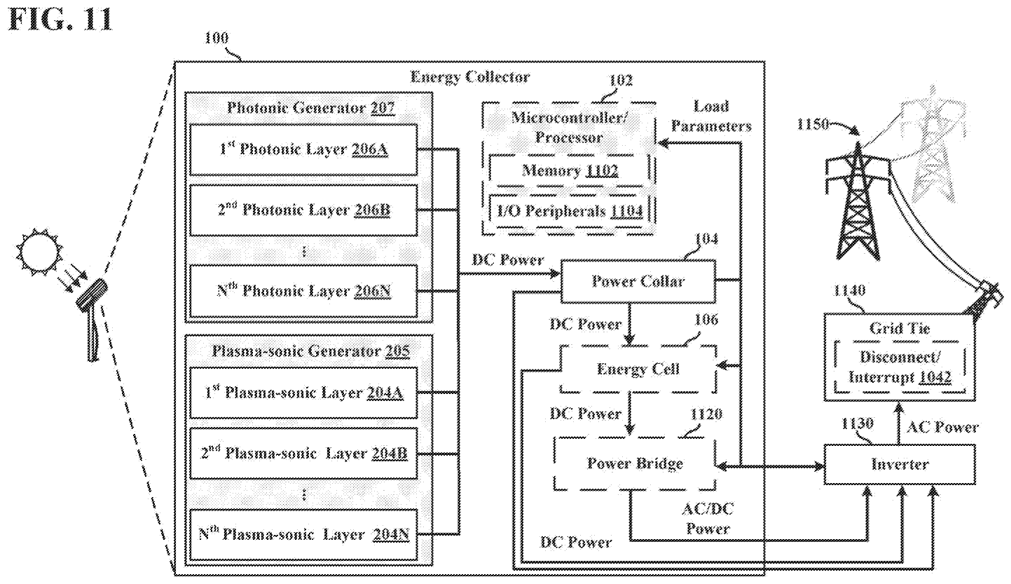

FIG. 8 illustrates an ISO view of an exemplary hybrid plasma-sonic-based photovoltaic collector 100 with bracketing couplers 120. The photovoltaic collector 100 is a triangular shape and includes a microcontroller/processor 102 to regulate the power transfer from an energy cell 106 to an inverter or grid tie. The microcontroller/processor 102 includes one or more programmable input/output peripherals 1104 ((FIG. 11) e.g., voltage sensor situated at an anode and/or cathode of the energy cell 106, communication interface circuit to communicate with a power bridge or power inverter) to balance the load and facilitate power distribution to the electrical grid. The microcontroller/processor 102 is positioned at or near an apex of a triangle corner 122.

The bracketing coupler 120 is “I” shaped so as to structurally interconnect with an edge of the photovoltaic collector 100. The bracketing coupler 120 extends along an edge length of the photovoltaic collector 100. In some examples, the bracketing coupler 120 is configured to electrically couple with the energy cell 106 so as to distribute power at the edges near an apex of a triangle corner 122. In some instances, the bracketing coupler 120 is configured with a power cable/coupler so as to transfer power from the energy cell 106 to an inverter or grid tie. In some examples, the bracketing coupler 120 is electrically insulated so as to prevent electrical power transfer from adjacent photovoltaic collectors 100. For example, bracketing couplers 120 are electrically insulated and situated at triangular apexes away from the microcontroller/processor 102. This configuration electrically isolates adjacent photovoltaic collectors 100 so that one or more photovoltaic collectors 100 can be disabled or disconnected without impeding the energy collection of the remaining photovoltaic collectors 100 in an array.

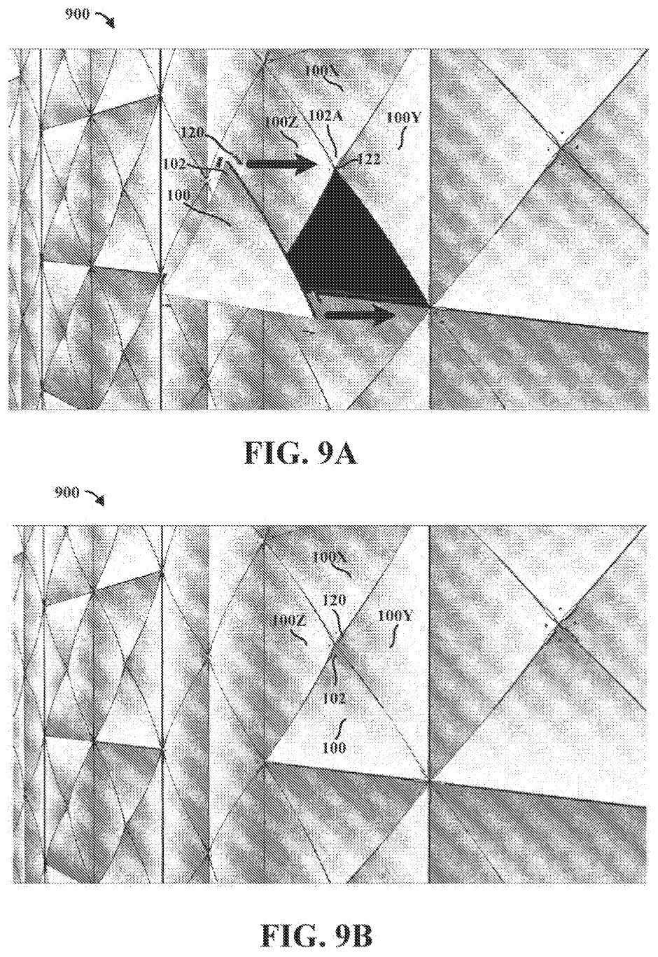

In some examples, the bracketing coupler 120 includes electrical switches so as to direct electrical power from one or more adjacent photovoltaic collectors. For example, an adjacent microcontroller/processor 102A (FIGS. 9A and 9B) can communicate with a microcontroller/processor 102 and indicate that an energy cell of the first adjacent photovoltaic cell 100X is not at full capacity. In turn, the microcontroller/processor 102A can (e.g., via one or more programmable input/output peripherals 1104 (FIG. 11)) throw a switch (e.g., relay, transistor, etc.) of the bracketing coupler 120 and direct power from the energy cell or generated from photonic absorption layer 206 (FIGS. 6A-6L, 6Q, and 6R) and/or plasma-sonic layer 204 (FIGS. 6A-6P) of the photovoltaic collectors 100 to charge the energy cell of the first adjacent photovoltaic cell 100X.

FIGS. 9A and 9B illustrate an array 900 of tessellated plasma-sonic-based collectors (e.g., 100, 100X, 100Y, 100Z). As depicted in FIG. 9A, the triangular photovoltaic collector 100 is configured to be positioned and in some instances electrically connected with a first adjacent triangular photovoltaic collector 100X, a second adjacent triangular photovoltaic collector 100Y, and a third adjacent triangular photovoltaic collector 100Z. An apex of a triangle corner of adjacent triangular photovoltaic collectors 100 is positioned with the microcontroller/processors 102 situated in proximity with each other. The proximity microcontroller/processor 102 facilitates communication between the first adjacent triangular photovoltaic collector 100X, the second adjacent triangular photovoltaic collector 100Y, and the third adjacent triangular photovoltaic collector 100Z.

FIG. 9B depicts the triangular photovoltaic collector 100 tessellated with the first adjacent triangular photovoltaic collector 100X, a second adjacent triangular photovoltaic collector 100Y, and a third adjacent triangular photovoltaic collector 100Z. It should be appreciated that the photovoltaic collector 100 can include various shapes. For example, a similar array can be tessellated with one or more of the plurality of photovoltaic collectors that have a triangular, a rectangular, a pentangular, a hexangular, an octangular shape, or other shape similar to the shapes depicted in FIG. 2.

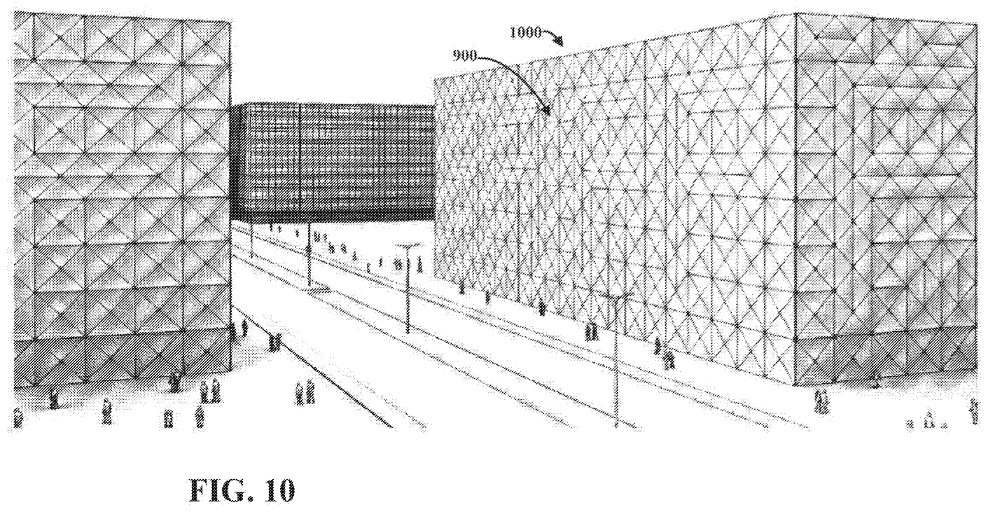

FIG. 10 illustrates one application of tessellated arrays 900, enveloping one or more buildings 1000. In this instance, the tessellated array 900 is a plurality of solar photovoltaic collectors (e.g., 100, 100X, 100Y, 100Z) that forms an additional exterior wall offset from an exterior surface of the building. As depicted in FIG. 10, the multiple triangular photovoltaic collectors (e.g., 100, 100X, 100X, 100Y, 100Z) form a covering (e.g., skin) around exterior wall of the building that envelopes at least a portion of the building. In some configurations, one or more of the triangular photovoltaic collectors (e.g., 100, 100X, 100Y, 100Z) are transparent so as to provide for viewing the features outside the building 900. In some examples, one or more of the triangular photovoltaic collectors (e.g., 100, 100X, 100Y, 100Z) are translucent so as to provide for sunlight to enter the building 900 while providing for privacy within the building 1000.

In some configurations, the tessellated array 900 is retrofitted outside the external wall/roof of an existing building 1000. In some instances, the tessellated array 900 includes mounting assembly (e.g., bracketing couplers 120, scaffolding, etc.) configured to bracket the plurality of solar photovoltaic collectors of building 1000. In some examples, the covering of the tessellated array 900 is integrated into the existing wall/roof of a building 1000. For example, one or more of the plurality of solar photovoltaic collectors (e.g., 100, 100X, 100Y, 100Z) is a window or a panel that separates interior from exterior of the building 1000.

FIG. 11 illustrates a conceptual data flow diagram illustrating the data flow between different hardware of a hybrid plasma-sonic-based photovoltaic collector 100 that implements a plasma-sonic generator 205 and a photonic generator 207. The plasma-sonic generator 205 generally describes one or more plasma-sonic layers (204A, 2048, . . . 204N, etc.) that facilitates capturing the oscillation of charged carriers (e.g., electrons, holes, etc.) of the nanoparticles in the plasma-sonic layer 204 at the second conduction layer 202B. The plasma-sonic generator 205 can include a first plasma-sonic layer 204A electrically coupled to a first conductor layer 202A as depicted in FIGS. 6O and 6P. The plasma-sonic generator 205 can also include a second plasma-sonic layer 204B parallel to the first plasma-sonic layer 204A and electrically coupled to a second conductor layer 202B, as depicted in FIGS. 6O and 6P. It is contemplated that the three or more plasma-sonic layers (e.g., N^{th} plasma-sonic layer) can be provided in the photovoltaic collector 100.

The photonic generator 207 generally describes one or more photonic absorption layers (206A, 206B, . . . 206N, etc.) that generate electron-hole pairs from incident light longer than specific wavelengths, which in turn induces a direct electric current. The photonic generator 207 can include a first photonic absorption layer 206A in parallel with the plasma-sonic generator 205. For example, FIGS. 5A, 5B, and 6A-6L depict the photonic absorption layer 206 stacked in parallel with the plasma-sonic layer 204. The photonic generator 207 can also include a second photonic absorption layer 206B parallel to the first photonic absorption layer 206A, analogous to the parallel configuration of the first plasma-sonic layer 204A and the second plasma-sonic layer 204B depicted in FIGS. 6O and 6P. It is contemplated that the two or more photonic absorption layer layers (e.g., N^{th} photonic absorption layer 206) can be provided in the photovoltaic collector 100.

The power collar 104 is electrically coupled to one or more programmable input/output peripherals 1104 from the microcontroller/processor 102. In some configuration, the power collar 104 includes the rectifier bridge circuitry 220, such as a half-wave bridge rectifier 222 or a full-wave rectifier bridge. The half-wave bridge rectifier 222 includes one or more diodes interconnected so as to covert a AC power signal 410 (depicted at test probe A of FIG. 4B) from the plasma-sonic photovoltaic cell cross-section 200 to a pulsed DC power signal 412 (depicted at test probe B of FIG. 4B) to a power collar 104 at a periphery of the photovoltaic collector 100. As discussed supra, the microcontroller/processor 102 includes one or more programmable input/output peripherals 1104 (e.g, voltage sensor situated at an anode and/or cathode of the energy cell 106, communication interface circuit to communicate with a power bridge or power inverter). The input/output peripherals 1104 are configured to sense load parameters from the power collar 104, an energy cell 106, a power bridge 1120, and an inverter 1130 and store each load parameter to memory 1102.

In one configuration, the power collar 104 is configured to provide DC power from the plasma-sonic generator 205 and/or the photonic generator 207 to an inverter 1130. In such a configuration the DC power generated from the plasma-sonic generator 205 and/or the photonic generator 207 is converted to AC power suitable for off grid application. As depicted in FIG. 11, the inverter 1130 can further provide AC power to a grid tie 1140 that is configured to provide AC power suitable for the power grid 1150. In some examples, the grid tie 1140 includes safety features to cease power transfer and electrifying the grid when an interrupt of instantaneous power (e.g., voltage, current) of the grid 1150 is sensed. For example, in some instances, the grid tie 1140 includes a disconnect/interrupt 1042 configured to sever power to the grid in the event of a detected disruption of instantaneous power (e.g., voltage, current) from the grid 1150.

In one optional configuration, the power collar 104 is configured to provide DC power to an energy cell 106. For example, the energy cell 106 provides a reservoir of charge carriers (e.g., electrons, holes, etc.) that lessens the variation in the rectified pulsed DC power signal 412 (depicted at test probe B of FIG. 4B) from the rectifier bridge circuitry 220. In turn, the DC power provided to the inverter 1130 is conditioned (e.g., smoothed), which can facilitate conversion from DC power to AC power suitable for the off-grid and on-grid applications.

In one optional configuration, the power collar 104 and/or the energy cell 106 are configured to provide DC power to a power bridge 1120. The power bridge 1120 is configured to balance the impedance between the power collar 104 and/or the energy cell 106 and inverter 1130 so as to optimize power transfer. In some examples, the power bridge 1120 retrieves the load parameters from the memory 1102 of the microcontroller/processor 102 and adjusts impedance of the power bridge 1120 to reduce signal reflections from the inverter 1130. In some examples, the power bridge 1120 is electrically coupled to the inverter 1130.

In some examples, the power bridge 1120 is a power transfer circuit affixed to the solar photovoltaic collector 100 and electrically coupled to the power collar 104 (e.g., at a first electrode and a second electrode). For example, the power bridge 1120 can include the microcontroller/processor 102 and the input/output peripherals 1104 to sense instantaneous power of an electrical power grid 1150, sense instantaneous power generated from the photovoltaic collector 100, and sweep power generated from the photovoltaic collector 100 to the electrical power grid 1150.

In some instances, the power bridge 1120 includes wireless transfer circuitry to transmit electrical energy from the power bridge 1120 to the inverter 1130 using time-varying electric, magnetic, or electromagnetic fields.

It is understood that the specific order or hierarchy of blocks in the processes/flowcharts disclosed is an illustration of exemplary approaches. Based upon design preferences, it is understood that the specific order or hierarchy of blocks in the processes/flowcharts can be rearranged. Further, some blocks can be combined or omitted. The accompanying method claims present elements of the various blocks in a sample order and are not meant to be limited to the specific order or hierarchy presented.

The previous description is provided to enable any person skilled in the art to practice the various examples described herein. Various modifications to these examples will be readily apparent to those skilled in the art, and the generic principles defined herein can be applied to other examples. Thus, the claims are not intended to be limited to the examples shown herein, but are to be accorded the fill scope consistent with the language of the claims, wherein reference to an element in the singular is not intended to mean “one and only one,” unless specifically so stated, but rather “one or more.” The word “exemplary” is used herein to mean “serving as an example, instance, or illustration.” Any example described herein as “exemplary” is not necessarily to be construed as preferred or advantageous over other examples. Unless specifically stated otherwise, the term “some” refers to one or more. Combinations, such as “at least one of A, B, or C;” “one or more of A, B, or C;” “at least one of A, B, and C;” “one or more of A, B, and C;” and “A, B, C; or any combination thereof” include any combination of A, B, and/or C, and can include multiples of A, multiples of B, or multiples of C. Specifically, combinations, such as “at least one of A, B, or C,” “one or more of A, B, or C.” “at least one of A, B, and C,” “one or more of A. B, and C,” and “A, B, C, or any combination thereof” can be A only, B only, C only, A and B, A and C, B and C, or A and B and C, where any such combinations can contain one or more member or members of A, B, or C. All structural and functional equivalents to the elements of the various examples described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like cannot be a substitute for the word “means.” As such, no claim element is to be construed under 35 U.S.C § 1.12(f) unless the element is expressly recited using the phrase “means for.”

1. A photovoltaic cell, comprising:
a first conduction layer;
a second conduction layer;
a photonic absorption layer electrically coupled to the first conduction layer, the photonic absorption layer is tuned to absorb incident light at a first wavelength of the incident light to generate a first electric current along the first conduction layer; and
a plasma-sonic layer electrically coupled to the photonic absorption layer and the second conduction layer, the plasma-sonic layer includes nanoparticles, the nanoparticles are tuned to a second wavelength of the incident light that induces electrons to oscillate at a surface of the nanoparticles.

2. The photovoltaic cell of claim 1, wherein the second conduction layer is configured to capture the oscillating electrons along the surface of the nanoparticles to generate a second electric current.

3. The photovoltaic cell of claim 1, wherein the first electric current is a direct current and the second electric current is an alternating current.

4. The photovoltaic cell of claim 1, wherein the first conduction layer is electrically coupled to the second conduction layer.

5. The photovoltaic cell of claim 1, further comprising a rectifier bridge configured to provide a same polarity of output with respect to reference ground for any polarity at a first input or second input, wherein the first input is electrically coupled to the second conduction layer and the second input is electrically coupled to the plasma-sonic layer.

6. The photovoltaic cell of claim 5, wherein the rectifier bridge is a full-wave rectifier or a half-wave rectifier.

7. The photovoltaic cell of claim 5, further comprising an energy cell electrically coupled across the output of the rectifier bridge and the reference ground.

8. The photovoltaic cell of claim 7, wherein the rectifier bridge includes a diode reverse bias across the plasma-sonic layer and the energy cell.

9. The photovoltaic cell of claim 7, wherein the energy cell is a nickel cadmium (NiCd) battery, nickel-metal hydride (NiMH) battery, lithium ion (Ii-on) battery, or a lithium polymer battery.

10. The photovoltaic cell of claim 7, wherein the energy cell is a supercapacitor, an electrolytic capacitor, a ceramic capacitor, or a film capacitor.

11. The photovoltaic cell of claim 5, wherein the rectifier bridge includes a first diode layer electrically coupled in reverse bias between the first conduction layer and the photonic absorption layer.

12. The photovoltaic cell of claim 5, wherein the rectifier bridge includes a second diode layer electrically coupled in reverse bias between the second conduction layer and the plasma-sonic layer.

13. The photovoltaic cell of claim 1, further comprising a substrate configured to hermetically seal the photonic absorption layer, the plasma-sonic layer, and the second conduction layer.

14. The photovoltaic cell of claim 1, wherein one or both of the first conduction layer and the second conduction layer include graphene.

15. The photovoltaic cell of claim 14, wherein the graphene is p-doped or n-doped.

16. The photovoltaic cell of claim 1, wherein capturing the oscillating electrons along the surface of the nanoparticles causes a temperature of the second conduction layer to decrease.

17. The photovoltaic cell of claim 1, wherein one or both of the first conductor layer and the second conductor layer includes conductive nanowires.

18. The photovoltaic cell of claim 1, further comprising a power gap layer electrically coupled to one or both of the first conductor layer and the second conductor layer with the conductive nanowires.

19. The photovoltaic cell of claim 1, wherein the second wavelength of the incident light is a resonance wavelength of the oscillating electrons.

20. The photovoltaic cell of claim 1, wherein the first wavelength of the incident light or the second wavelength of the incident light is longer than 700 nanometers.

21. The photovoltaic cell of claim 1, wherein the first wavelength of the incident light is longer than the second wavelength of the incident light.

22. The photovoltaic cell of claim 1, wherein the first wavelength of the incident light is shorter than the second wavelength of the incident light.

23. The photovoltaic cell of claim 1, wherein the plasma-sonic layer is an electrical insulator.

24. The photovoltaic cell of claim 1, wherein the plasma-sonic layer is a dielectric with a complex dielectric constant.

25. The photovoltaic cell of claim 1, wherein the plasma-sonic layer is a polymer or a ceramic.

26. The photovoltaic cell of claim 1, wherein the plasma-sonic layer is a polycarbonate.

27. The photovoltaic cell of claim 1, wherein the nanoparticles are homogenously suspended in the plasma-sonic layer.

28. The photovoltaic cell of claim 1, wherein the nanoparticles have a conical, rectangular, bi-pyramidal, tetrahedral, cubical, octahedral, cylindrical, ellipsoidal, or spherical shape.

29. The photovoltaic cell of claim 1, wherein the nanoparticles are electrically insulating or electrically semiconducting.

30. The photovoltaic cell of claim 1, wherein the first wavelength is proportional to sizes of quantum dots in the photonic absorption layer.

31. The photovoltaic cell of claim 1, wherein the photonic absorption layer includes light scattering particles.

32. The photovoltaic cell of claim 1, wherein the first conduction layer, the second conduction layer, the plasma-sonic layer, and the photonic absorption layer are translucent or transparent to the incident light within the visible spectrum at a zero degree incident angle.

33. The photovoltaic cell of claim 1, wherein a combination of the first conduction layer, the second conduction layer, the plasma-sonic layer, and the photonic absorption layer has a transmittance of light within the visible spectrum greater than 0.76 at a zero degree incident angle.

34. The photovoltaic cell of claim 1, further comprising a reflector provided on a distal surface of the photovoltaic cell opposite a surface of incident light, wherein the reflector is configured to reflect incident light back towards the surface of incident light.

35. The photovoltaic cell of claim 1, wherein the photovoltaic cell is flat or planar.

36. The photovoltaic cell of claim 1, wherein the photovoltaic cell is non-planar along a light incident surface.

37. The photovoltaic cell of claim 37, wherein the photovoltaic cell is curved along a light incident surface at an arc angle between 0 to 23.5 degrees.

38. The photovoltaic cell of claim 1, wherein the photovoltaic cell has a triangular, rectangular, pentangular, hexangular, elliptical, or circular shape.

39. A solar photovoltaic collector, comprising:
a photovoltaic cell of claim 1;
a first electrode electrically coupled to the first conduction layer, and a second electrode electrically coupled to the plasma-sonic layer and the photonic absorption layer, wherein the first electrode is electrically isolated from the second electrode.

40. The solar photovoltaic collector of claim 39, wherein the first electrode and the second electrode are situated around peripheral surfaces of the solar photovoltaic collector.

41. The solar photovoltaic collector of claim 39, further comprising: a power transfer circuit affixed to the photovoltaic collector and electrically coupled to the first electrode and the second electrode, wherein the power transfer circuit is configured to:
sense instantaneous power of an electrical power grid,
sense instantaneous power generated from the photovoltaic collector, and
sweep power generated from the photovoltaic collector to the electrical power grid.

42. The solar photovoltaic collector of claim 41, wherein the power transfer circuit includes circuitry to transfer the power wirelessly to the electrical power grid.

43. A solar photovoltaic collector array, comprising:
a plurality of solar photovoltaic collectors of claim 39, configured to tessellate with each other.

44. The solar photovoltaic collector array of claim 43, wherein one or more of the plurality of photovoltaic collector has a triangular, rectangular, pentangular, hexangular, or octangular shape.

45. The solar photovoltaic collector array of claim 43, further comprising a mounting assembly configured to bracket the plurality of solar photovoltaic collectors of a building.

46. The solar photovoltaic collector array of claim 45, wherein one or more of the plurality of solar photovoltaic collectors is a window or a panel that separates interior from exterior of the building.

47. The solar photovoltaic collector array of claim 45, wherein the plurality of solar photovoltaic collectors forms an additional exterior wall offset from an exterior surface of the building.

48. The solar photovoltaic collector array of claim 47, wherein the additional exterior wall envelopes a portion of the building.
